(19) United States
(12) Patent Application Publication
(10) Pub. No.: US 2026/0247618 A1
(43) Pub. Date: Aug. 20, 2026

(54) SEMICONDUCTOR MEMORY DEVICE

(71) Applicant: Kioxia Corporation, Tokyo (JP)

(72) Inventors: Susumu SAITO, Yokkaichi Mie (JP); Koichi SAKATA, Yokkaichi Mie (JP)

(21) Appl. No.: 19/294,958

(22) Filed: Aug. 8, 2025

(30) Foreign Application Priority Data
Feb. 18, 2025 (JP) 2025-024307

(51) Int. Cl. H10B 43/27; H10B 43/10; H10B 43/35

(52) U.S. Cl. CPC H10B 43/27; H10B 43/10; H10B 43/35

(57) ABSTRACT

A semiconductor memory device includes a semiconductor substrate and a memory cell array. The memory cell array includes a plurality of word lines provided between a source line and a first wiring, and a memory pillar. The memory pillar includes a core member extending through each of the plurality of word lines, a semiconductor film provided around a side surface of the core member, a semiconductor portion extending through the first wiring and electrically connected to the semiconductor film, a cap portion extending in the semiconductor portion, and a laminate of films covering a side surface of the semiconductor film and a side surface of the semiconductor portion. The semiconductor portion is formed of an n-type semiconductor containing an impurity. A side surface of the cap portion and a surface of the cap portion facing the core member are covered by the semiconductor portion.

### CROSS-REFERENCE TO RELATED APPLICATION

This application is based upon and claims the benefit of priority from Japanese Patent Application No. 2025-024307, filed Feb. 18, 2025, the entire contents of which are incorporated herein by reference.

### FIELD

Embodiments described herein relate generally to a semiconductor memory device.

### BACKGROUND

A NAND flash memory is known as a semiconductor memory device capable of storing data in a non-volatile manner. In the NAND flash memory, a three-dimensional memory structure is adopted in order to achieve high integration and large capacity.

### BRIEF DESCRIPTION OF THE DRAWINGS

FIG. 1 is a block diagram showing an example of a configuration of a memory system including a semiconductor memory device according to an embodiment.

FIG. 2 is a circuit diagram showing an example of a circuit configuration of a memory cell array provided in the semiconductor memory device according to the embodiment.

FIG. 3 is a plan view diagram showing an example of a planar layout of the memory cell array provided in the semiconductor memory device according to the embodiment.

FIG. 4 is a plan view diagram showing an example of a planar layout of the memory cell array provided in the semiconductor memory device according to the embodiment.

FIG. 5 is a cross-sectional diagram showing an example of a cross-sectional structure of the memory cell array of the semiconductor memory device according to the embodiment.

FIG. 6 is a cross-sectional diagram showing an example of a cross-sectional structure of a memory pillar of the semiconductor memory device according to the embodiment.

FIG. 7 is a cross-sectional diagram showing an example of a cross-sectional structure of the memory pillar of the semiconductor memory device according to the embodiment.

FIG. 8 is a cross-sectional diagram showing an example of a cross-sectional structure of the memory cell array of the semiconductor memory device according to the embodiment.

FIG. 9 is a cross-sectional diagram showing an example of a cross-sectional structure of the semiconductor memory device according to the embodiment.

FIG. 10 is a cross-sectional diagram showing an example of a cross-sectional structure of a connection pad of the semiconductor memory device according to the embodiment.

FIGS. 11-22 are cross-sectional diagrams for illustrating an example of process steps of a method for manufacturing the semiconductor memory device according to the embodiment.

FIG. 23 is a cross-sectional diagram showing an example of a cross-sectional structure of a memory cell array of a semiconductor memory device according to a first modification.

FIG. 24 is a cross-sectional diagram showing an example of a cross-sectional structure of the memory cell array of the semiconductor memory device according to the first modification.

FIGS. 25-27 are cross-sectional diagrams for illustrating an example of process steps of a method for manufacturing the semiconductor memory device according to the first modification.

FIG. 28 is a cross-sectional diagram showing an example of a cross-sectional structure of a memory cell array of a semiconductor memory device according to a second modification.

FIGS. 29-31 are cross-sectional diagrams for illustrating an example of process steps of a method for manufacturing the semiconductor memory device according to the second modification.

FIG. 32 is a cross-sectional diagram showing an example of a cross-sectional structure of a memory cell array of a semiconductor memory device according to a third modification.

FIG. 33 is a cross-sectional diagram showing an example of a cross-sectional structure of a memory cell array of a semiconductor memory device according to a fourth modification.

FIG. 34 is a cross-sectional diagram showing an example of a cross-sectional structure of a memory pillar of a the semiconductor memory device according to the fourth modification.

FIG. 35 is a cross-sectional diagram for illustrating an example of a process step of a method for manufacturing the semiconductor memory device according to the fourth modification.

FIG. 36 is a cross-sectional diagram showing an example of a cross-sectional structure of a memory cell array of a semiconductor memory device according to a fifth modification.

FIGS. 37-41 are cross-sectional diagrams for illustrating an example of process steps of a method for manufacturing the semiconductor memory device according to the fifth modification.

### DETAILED DESCRIPTION

In general, according to an embodiment, a semiconductor memory device includes a substrate and a memory cell array. The memory cell array includes a source line provided along a surface of the substrate, a plurality of word lines arranged in a first direction intersecting with the surface of the substrate, each of the word lines extending in a second direction along the surface of the substrate, a first wiring extending in the second direction, the plurality of word lines being between the source line and the first wiring in the first direction, and a memory pillar extending from the source line in the first direction, intersecting with the plurality of word lines and the first wiring. The memory pillar comprises a core member extending in the first direction through each of the plurality of word lines, a semiconductor film provided around a side surface of the core member, a semiconductor portion extending in the first direction through the first wiring and electrically connected to the semiconductor film, the semiconductor portion being formed of an n-type semiconductor containing an impurity, a cap portion extending in the first direction in the semiconductor portion, a side surface of the cap portion and a surface of the cap portion facing the core member being covered by the semiconductor portion, and a laminate of films covering a side surface of the semiconductor film and a side surface of the semiconductor portion.

Hereinafter, embodiments will be described with reference to the accompanying drawings. The dimensions and proportions of the drawings are not necessarily the same as those in reality. In the following description, components having substantially the same functions and configurations are given the same reference numerals. In addition, when elements having similar configurations are to be particularly distinguished from each other, different letters or numbers may be added to the end of the same reference numerals.

### 1. Embodiment

Hereinafter, a semiconductor memory device according to an embodiment will be described.

### 1.1 Configuration

A configuration of the semiconductor memory device according to the embodiment will be described.

### 1.1.1 Memory System

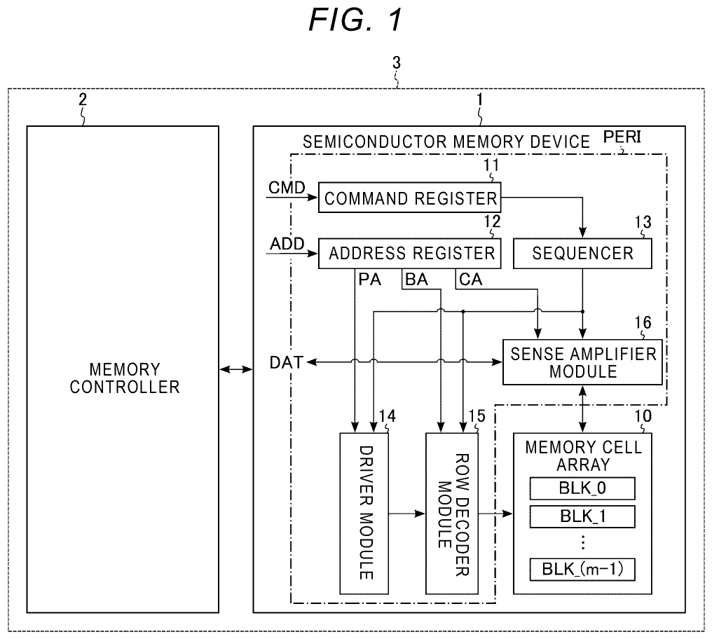

First, an example of a configuration of a memory system will be described using FIG. 1. FIG. 1 is a block diagram showing an example of the configuration of the memory system including the semiconductor memory device according to the embodiment.

A memory system 3 is, for example, a solid state drive (SSD) or an SD™ card. The memory system 3 is connected to, for example, an external host device (not shown). The memory system 3 stores data from the host device. The memory system 3 reads data to the host device.

The memory system 3 includes a semiconductor memory device 1 and a memory controller 2.

The semiconductor memory device 1 is, for example, a NAND flash memory. The semiconductor memory device 1 stores data in a non-volatile manner. In the following, a case where the semiconductor memory device 1 is the NAND flash memory will be described as an example.

The memory controller 2 is configured with, for example, an integrated circuit such as a system-on-a-chip (SoC). The memory controller 2 writes data to the semiconductor memory device 1 based on, for example, a request from the host device. The memory controller 2 reads data from the semiconductor memory device 1 based on, for example, a request from the host device. The memory controller 2 transmits data read from the semiconductor memory device 1 to the host device.

Communication between the semiconductor memory device 1 and the memory controller 2 complies with, for example, a single data rate (SDR) interface, a toggle double data rate (DDR) interface, or an open NAND flash interface (ONFI).

### 1.1.2 Semiconductor Memory Device

The configuration of the semiconductor memory device 1 will be described with reference to FIG. 1. The semiconductor memory device 1 includes, for example, a memory cell array 10 and a peripheral circuit PERI. The peripheral circuit PERI includes, for example, a command register 11, an address register 12, a sequencer 13, a driver module 14, a row decoder module 15, and a sense amplifier module 16.

The memory cell array 10 includes a plurality of blocks BLK0 to BLK(m-1) (m is an integer of 2 or more). A block BLK is a set of memory cells capable of storing data in a non-volatile manner. The block BLK is used, for example, as a data erase unit. The memory cell array 10 is also provided with a plurality of bit lines and a plurality of word lines. One memory cell is associated with, for example, one bit line and one word line.

The command register 11 stores a command CMD that the semiconductor memory device 1 receives from the memory controller 2. The command CMD includes, for example, a command to cause the sequencer 13 to execute a read operation, a write operation, an erase operation, and the like.

The address register 12 stores address information ADD that the semiconductor memory device 1 receives from the memory controller 2. The address information ADD includes, for example, a page address PA, a block address BA, and a column address CA. The page address PA, the block address BA, and the column address CA are used, for example, to select a word line, a block BLK, and a bit line, respectively.

The sequencer 13 controls the overall operation of the semiconductor memory device 1. The sequencer 13 executes a read operation, a write operation, and an erase operation based on the command CMD stored in the command register 11.

The driver module 14 generates voltages used in the read operation, the write operation, the erase operation, and the like. Then, the driver module 14 applies the generated voltage to a signal line corresponding to a selected word line based on, for example, the page address PA stored in the address register 12.

The row decoder module 15 selects one block BLK in the corresponding memory cell array 10 based on the block address BA stored in the address register 12. Then, the row decoder module 15 transfers, for example, the voltage applied to the signal line corresponding to the selected word line to a selected word line in the selected block BLK.

In the write operation, the sense amplifier module 16 transfers write data DAT received from the memory controller 2 to the memory cell array 10. In the read operation, the sense amplifier module 16 executes a determination of data stored in the memory cell based on the voltage of the bit line. The sense amplifier module 16 transfers the result of the determination to the memory controller 2 as read data DAT.

### 1.1.3 Circuit Configuration of Memory Cell Array

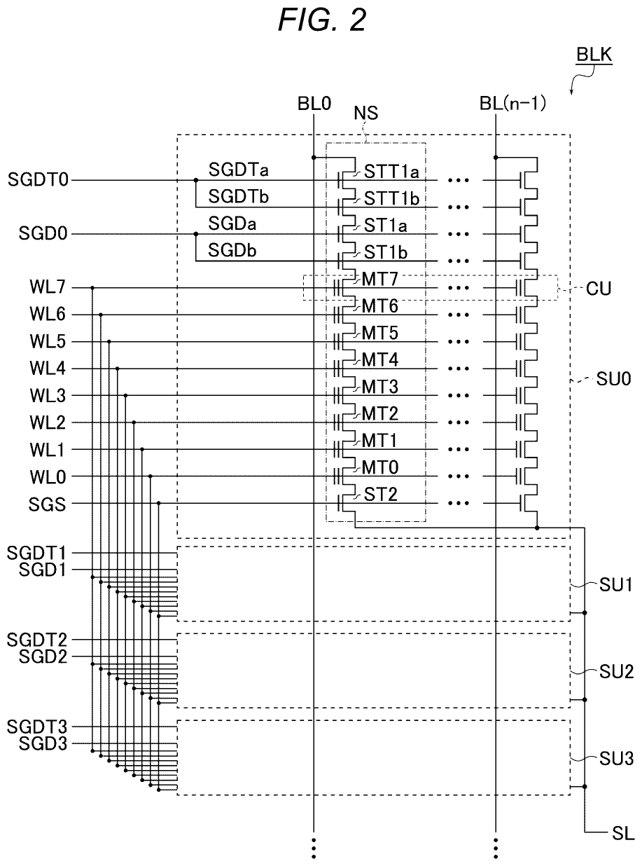

An example of a circuit configuration of the memory cell array 10 will be described with reference to FIG. 2. FIG. 2 is a circuit diagram showing an example of the circuit configuration of the memory cell array provided in the semiconductor memory device according to the embodiment. FIG. 2 shows one block BLK among the plurality of blocks BLK in the memory cell array 10. In the example shown in FIG. 2, the block BLK includes four string units SU0, SU1, SU2, and SU3. In the following description, when the string units SU0 to SU3 are not distinguished from each other, each of the string units SU0 to SU3 is simply referred to as a string unit SU.

Each string unit SU includes a plurality of NAND strings NS respectively associated with bit lines BL0 to BL(n-1) (n is an integer of 2 or more). Each NAND string NS includes, for example, memory cell transistors MT0 to MT7 and select transistors STT1a, STT1b, ST1a, ST1b, and ST2. In the following description, when the bit lines BL0 to BL(n-1) are not distinguished from each other, each of the bit lines BL0 to BL(n-1) will be simply referred to as a bit line BL. When the memory cell transistors MT0 to MT7 are not distinguished from one another, each of the memory cell transistors MT0 to MT7 is simply referred to as a memory cell transistor MT. When the select transistors STT1a and STT1b are not distinguished from one another, each of the select transistors STT1a and STT1b is simply referred to as a select transistor STT1. When the select transistors ST1a and ST1b are not distinguished from each other, each of the select transistors ST1a and ST1b is simply referred to as a select transistor ST1.

Each of the memory cell transistors MT0 to MT7 includes a control gate and a charge storage film. Each of the memory cell transistors MT0 to MT7 stores data in a non-volatile manner. The select transistors ST1 and ST2 are used to select the string unit SU during various operations. The select transistor STT1 is used to select the string unit SU during a write operation and a read operation, similar to the select transistors ST1 and ST2. The select transistor STT1 is also used to generate a gate induced drain leakage (GIDL) current during an erase operation. The numbers of select transistors ST1 and STT1 may be freely selected, and each of the numbers may be one or more.

In each NAND string NS, the memory cell transistors MT0 to MT7 are connected in series. The select transistors STT1a, STT1b, ST1a, and ST1b are connected in series in this order. One end of the select transistor STT1a among the select transistors STT1a, STT1b, ST1a, and ST1b is connected to the bit line BL associated with the select transistors STT1a, STT1b, ST1a, and ST1b. The other end of the select transistor ST1b among the select transistors STT1a, STT1b, ST1a, and ST1b is connected to one end of the memory cell transistors MT0 to MT7 connected in series. One end of the select transistor ST2 is connected to the other end of the memory cell transistors MT0 to MT7 connected in series. The other end of the select transistor ST2 is connected to the source line SL.

In each block BLK, the control gates of the memory cell transistors MT0 to MT7 are connected to the word lines WL0 to WL7, respectively. In the following description, when the word lines WL0 to WL7 are not distinguished from one another, each of the word lines WL0 to WL7 is simply referred to as a word line WL.

The string units SU0 to SU3 correspond to select gate lines SGDT0 to SGDT3, respectively. In the following description, when the select gate lines SGDT0 to SGDT3 are not distinguished from one another, each of the select gate lines SGDT0 to SGDT3 is simply referred to as a select gate line SGDT. In each string unit SU, gates of the select transistors STT1a and STT1b are commonly connected to the select gate line SGDT corresponding to that string unit SU among the select gate lines SGDT0 to SGDT3. Specifically, in the string unit SU0, the gate of select transistor STT1a is connected to a select gate line SGDTa. The gate of select transistor STT1b is connected to a select gate line SGDTb. The select gate lines SGDTa and SGDTb are commonly connected to the select gate line SGDT0.

The string units SU0 to SU3 correspond to select gate lines SGD0 to SGD3, respectively. When the select gate lines SGD0 to SGD3 are not distinguished from one another, each of the select gate lines SGD0 to SGD3 is simply referred to as a select gate line SGD. In each string unit SU, the gates of the select transistors ST1a and ST1b are commonly connected to the select gate line SGD corresponding to that string unit SU among the select gate lines SGD0 to SGD3. Specifically, in the string unit SU0, the gate of the select transistor ST1a is connected to a select gate line SGDa. The gate of the select transistor ST1b is connected to a select gate line SGDb. The select gate lines SGDa and SGDb are commonly connected to the select gate line SGD0.

In each block BLK, the gates of the plurality of select transistors ST2 are commonly connected to a select gate line SGS. However, the embodiment is not limited to this, and the gates of the plurality of select transistors ST2 may be connected to a plurality of select gate lines SGS that are different for each string unit SU.

A different column address CA is assigned to each of the bit lines BL0 to BL(n-1). Each bit line BL is shared by NAND strings NS to which the same column address CA is assigned among the plurality of blocks BLK. The word lines WL0 to WL7 are provided for each block BLK. The source line SL is shared, for example, among the plurality of blocks BLK.

A set of memory cell transistors MT connected to a common word line WL in one string unit SU is referred to as, for example, a cell unit CU. A storage capacity of the cell unit CU including the plurality of memory cell transistors MT, each of which stores one-bit data, is defined, for example, as “one-page data”. The cell unit CU may have a storage capacity of two-or-more page data depending on the number of bits of data stored in each memory cell transistor MT.

The circuit configuration of the memory cell array 10 is not limited to the configuration described above. For example, the number of string units SU provided in each block BLK may be freely selected. The number of memory cell transistors MT and select transistors STT1, ST1, and ST2 provided in each NAND string NS may be freely selected.

### 1.1.4 Structure of Semiconductor Memory Device

An example of the structure of the semiconductor memory device 1 according to an embodiment will be described.

In the following description, the X-direction is a direction approximately parallel to a semiconductor substrate of the semiconductor memory device 1. The X-direction corresponds to the extending direction of the word lines WL. The Y-direction is a direction approximately parallel to the semiconductor substrate and perpendicular to the X-direction. The Y-direction corresponds to the extending direction of the bit line BL. The Z1-direction and the Z2-direction are directions approximately perpendicular to the semiconductor substrate. The Z1-direction corresponds to the direction from the semiconductor substrate of the semiconductor memory device 1 toward an electrode pad. The Z2-direction corresponds to the direction from the electrode pad toward the semiconductor substrate. When the Z1-direction and the Z2-direction are not distinguished, each of the Z1-direction and the Z2-direction is simply referred to as the Z-direction. In the following, the Z2-direction side with respect to a certain component will be referred to as one side in the Z-direction (or simply one side), and the Z1-direction side with respect to a certain component will be referred to as the other side in the Z-direction (or simply the other side). Furthermore, a surface of a certain component facing the electrode pad will be referred to as a first surface, and a surface of a certain component facing the semiconductor substrate will be referred to as a second surface. The first surface and second surface can also be referred to as a surface on the other side in the Z-direction and a surface on one side in the Z-direction, respectively.

### 1.1.4.1 Structure of Memory Cell Array

An example of the structure of the memory cell array 10 will be described.

### 1.1.4.1.1 Overall Configuration of Memory Cell Array

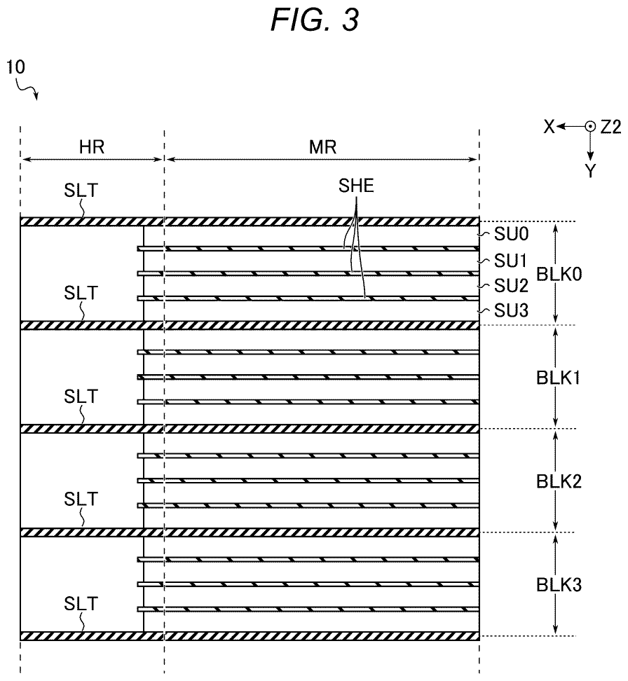

The overall configuration of the memory cell array 10 will be described with reference to FIG. 3. FIG. 3 is a plan view diagram showing an example of a planar layout of a memory cell array provided in the semiconductor memory device according to the embodiment. FIG. 3 shows areas corresponding to four blocks BLK0 to BLK3.

The memory cell array 10 includes a stacked wiring structure and a plurality of members SLT and SHE. The stacked wiring structure includes the select gate lines SGDTa, SGDTb, SGDa, SGDb, and SGS, and the plurality of word lines WL. The stacked wiring structure is a structure in which the select gate lines SGDTa, SGDTb, SGDa, SGDb, and SGS, and the plurality of word lines WL are stacked along the Z-direction according to the number of stacked layers. In the following description, the select gate lines SGDTa, SGDTb, SGDa, SGDb, and SGS, and the word lines WL are also collectively referred to as a stacked wiring.

The stacked wiring structure is provided over a memory region MR and a lead-out region HR in the X-direction, for example.

The memory region MR is a region in which data is actually stored.

The lead-out region HR is a region used to connect the stacked wiring to the peripheral circuit PERI such as the row decoder module 15.

Each member SLT extends in the X-direction. Each member SLT crosses the stacked wiring structure in the X-direction across the memory region MR and the lead-out region HR. Each member SLT has a structure (closed structure) in which, for example, an insulator or a plate-shaped conductor is embedded inside. Each member SLT divides adjacent stacked wirings via the member SLT. Each of regions partitioned by the plurality of members SLT corresponds to one block BLK. In the example of FIG. 3, blocks BLK0, BLK1, BLK2, and BLK3 are arranged in this order.

Each member SHE extends in the X-direction. In the embodiment, a case in which three members SHE are provided between adjacent members SLT will be described. Each member SHE crosses the stacked wiring structure in the X-direction across the memory region MR. Each member SHE has a structure in which an insulator is embedded, for example. Each member SHE divides adjacent select gate lines SGD and SGDT via the member SHE, for example. Each of regions partitioned by the plurality of members SLT and SHE corresponds to one string unit SU. In the example of FIG. 3, the string units SU0, SU1, SU2, and SU3 are arranged in this order.

In the memory cell array 10, for example, the planar layout shown in FIG. 3 is repeatedly disposed in the Y-direction.

The planar layout of the memory cell array 10 is not limited to the layout described above. For example, the number of members SHE disposed between adjacent members SLT may be designed to be any number depending on the number of string units SU provided in the block BLK.

### 1.1.4.1.2 Structure of Memory Cell Array in Memory Region

The structure of the memory cell array 10 in the memory region MR will be described.

### 1.1.4.1.2.1 Planar Structure

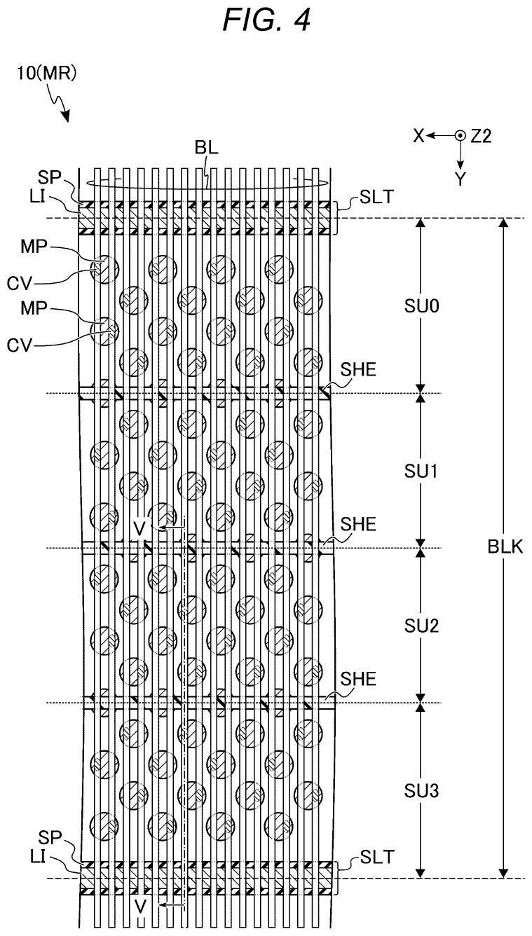

The planar structure of the memory cell array 10 in the memory region MR will be described with reference to FIG. 4. FIG. 4 is a plan view diagram showing an example of a planar layout of the memory cell array provided in the semiconductor memory device according to the embodiment.

In the memory region MR, the memory cell array 10 includes a plurality of memory pillars MP, a plurality of contacts CV, and a plurality of bit lines BL. Each member SLT includes a core portion LI and a spacer SP.

Each memory pillar MP functions as, for example, one NAND string NS. The plurality of memory pillars MP are arranged in a staggered pattern of, for example, 19 columns in a region between two adjacent members SLT. For example, counting from the string unit SU0 side among the string units SU0 to SU3, one member SHE overlaps each of a fifth-column memory pillar MP, a tenth-column memory pillar MP, and a fifteenth-column memory pillar MP.

Each of the plurality of bit lines BL extends in the Y-direction. The plurality of bit lines BL are also arranged in the X-direction. Each bit line BL overlaps at least one memory pillar MP for each string unit SU. In the example of FIG. 4, each bit line BL overlaps two memory pillars MP for each string unit SU. One of the plurality of bit lines BL overlapping the memory pillar MP is connected to that memory pillar MP via a contact CV. For example, no contact is provided between the memory pillar MP overlapping the member SHE and the bit line BL. That is, the memory pillar MP overlapping the member SHE is not electrically connected to the bit line BL.

The core portion LI is a conductor extending in the X-direction. The spacer SP is an insulator provided on a side surface of the core portion LI. The core portion LI is sandwiched between the spacers SP. The core portion LI and the stacked wiring adjacent to the core portion LI in the Y-direction are electrically isolated by the spacer SP. With this configuration, the core portion LI and the stacked wiring adjacent to the core portion LI in the Y-direction are electrically insulated from each other.

### 1.1.4.1.2.2 Cross-Sectional Structure

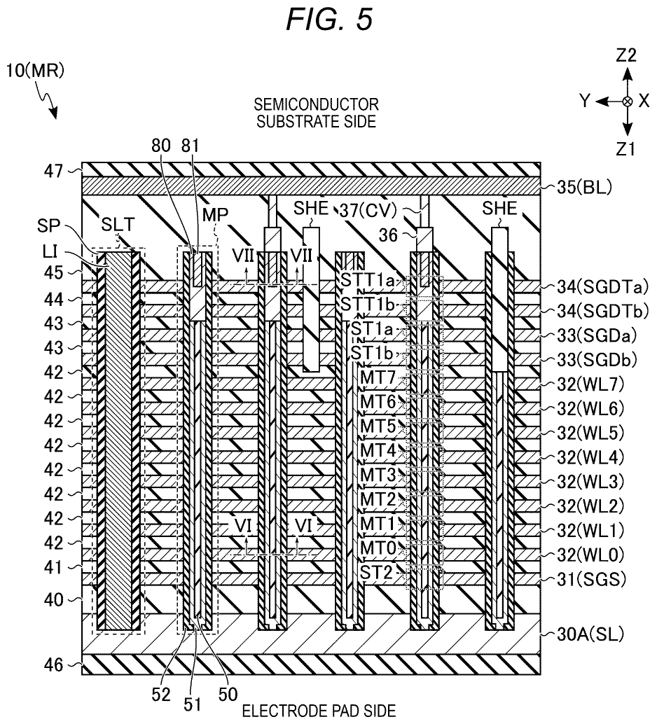

A cross-sectional structure of the memory region MR of the memory cell array 10 will be described with reference to FIG. 5. FIG. 5 is a cross-sectional diagram showing an example of the cross-sectional structure of the memory cell array of the semiconductor memory device according to the embodiment. The cross-sectional view of FIG. 5 is a cross-sectional view taken along line V-V in FIG. 4.

The memory cell array 10 further includes conductor layers 30A, 31, and 35, a plurality of conductor layers 32, 33, 34, 36, and 37, insulator layers 40, 41, 44, 45, 46, and 47, and a plurality of insulator layers 42 and 43. In FIG. 5, five memory pillars MP among the plurality of memory pillars MP are shown. The memory cell array 10 is provided between the electrode pads and the semiconductor substrate of the semiconductor memory device 1 in the Z-direction.

The conductor layer 30A is formed, for example, in a plate shape extending along the XY plane. The conductor layer 30A is used as the source line SL. The conductor layer 30A is made of a conductive material. The conductive material includes, for example, an n-type semiconductor to which impurities are added or a metal material.

The insulator layer 40 is stacked on a second surface of the conductor layer 30A. The conductor layer 31 is stacked on the second surface of the insulator layer 40. The conductor layer 31 is formed, for example, in a plate shape extending along the XY plane. The conductor layer 31 is used as the select gate line SGS. The conductor layer 31 contains, for example, tungsten (W) or molybdenum (Mo).

The insulator layer 41 is stacked on a second surface of the conductor layer 31. On a second surface of the insulator layer 41, eight conductor layers 32 and eight insulator layers 42 are stacked in the order of conductor layer 32, insulator layer 42, . . . , conductor layer 32, and insulator layer 42 toward the Z2-direction. The conductor layer 32 is formed, for example, in a plate shape extending along the XY plane. The eight conductor layers 32 are used as word lines WL0 to WL7 in order along the Z2-direction, respectively. The conductor layer 32 contains, for example, tungsten or molybdenum.

On a second surface of the insulator layer 42 closest to one side in the Z-direction among the eight insulator layers 42, two conductor layers 33 and two insulator layers 43 are stacked in the order of conductor layer 33, insulator layer 43, conductor layer 33, and insulator layer 43 toward the Z2-direction. The conductor layer 33 is formed, for example, in a plate shape extending along the XY plane. The conductor layer 33 on the other side is used as the select gate line SGDb. The conductor layer 33 on one side is used as the select gate line SGDa. The conductor layer 33 contains, for example, tungsten or molybdenum.

On a second surface of the insulator layer 43 on one side, two conductor layers 34 and one insulator layer 44 are stacked in the order of conductor layer 34, insulator layer 44, and conductor layer 34 toward the Z2-direction. The conductor layer 34 is formed, for example, in a plate shape extending along the XY plane. The conductor layer 34 on the other side is used as the select gate line SGDTb. The conductor layer 34 on one side is used as the select gate line SGDTa. The conductor layer 34 contains, for example, tungsten or molybdenum.

The two conductor layers 33 and the two conductor layers 34 are electrically insulated for each string unit SU by, for example, a plurality of members SHE.

On a second surface of the conductor layer 34 on one side (select gate line SGDTa), the insulator layer 45 is stacked. On a second surface of the insulator layer 45, a plurality of conductor layers 35 are stacked. Each conductor layer 35 is provided to extend along the Y-direction. Each conductor layer 35 functions as the bit line BL. Each conductor layer 35 is electrically connected to a plurality of memory pillars MP via a plurality of conductor layers 36 and 37.

The stacked structure including the conductor layers 30A and 31 to 37 and the insulator layers 40 to 45 as described above is surrounded by an insulator. FIG. 5 shows the insulator layer 46 in contact with the first surface of the conductor layer 30A and the insulator layer 47 in contact with the second surface of the conductor layer 35. Although not shown in FIG. 5, as will be described below, the conductor layer 30A is connected to the peripheral circuit PERI via a conductor layer on the other side with respect to the conductor layer 30A, for example. Although not shown in FIG. 5, as will be described below, the conductor layer 35 is connected to the peripheral circuit PERI via a conductor layer on one side with respect to the conductor layer 35.

On the other side of the conductor layer 35, a plurality of memory pillars MP are provided extending along the Z-direction. The plurality of memory pillars MP penetrate the conductor layers 31 to 34.

Each of the plurality of memory pillars MP includes, for example, a core member 50, a semiconductor film 51, a laminate of films 52, a semiconductor portion 80, and a cap portion 81. The core member 50 is provided to extend along the Z-direction. The semiconductor film 51 covers the periphery of the core member 50. The semiconductor film 51 is in contact with the conductor layer 30A. The semiconductor portion 80 and the cap portion 81 are provided on one side of the core member 50 and the semiconductor film 51 in the Z-direction. The cap portion 81 is provided, for example, in a columnar shape having a substantially uniform width along the Z-direction. The semiconductor portion 80 covers a side surface and first surface of the cap portion 81. The semiconductor portion 80 is in contact with the second surface of the core member 50 and the semiconductor film 51, for example. The laminate of films 52 covers a portion of the side surface and a portion of the first surface of the semiconductor film 51 excluding a portion where the semiconductor film 51 and the conductor layer 30A are in contact with each other, and a side surface of the semiconductor portion 80. The core member 50 contains an insulator such as silicon oxide. The semiconductor film 51 contains, for example, silicon. The semiconductor portion 80 is, for example, an n-type semiconductor in which impurities are added to a semiconductor such as polysilicon. The impurities include, for example, phosphorus (P) or arsenic (As). The cap portion 81 is a conductor. The cap portion 81 contains, for example, a metal material. The metal material includes, for example, at least one of tungsten and titanium nitride (TiN). The configuration of the laminate of films 52 will be described below. With the configuration described as above, in the memory pillar MP, the semiconductor portion 80 is provided in a region excluding the cap portion 81, of a region surrounded by the second surface of the core member 50, the second surface of the semiconductor film 51, and a part of the laminate of films 52 on one side of the semiconductor film 51, in a liner shape.

On the second surface of the semiconductor portion 80 and the cap portion 81, the conductor layer 36 is provided. The conductor layer 36 functions, for example, as a columnar contact. On a second surface of the conductor layer 36, the conductor layer 37 is provided. The conductor layer 37 functions, for example, as the contact CV.

With the configuration described as above, the cap portion 81 and the conductor layers 36 and 37 electrically connect the semiconductor portion 80 and the semiconductor film 51 to the conductor layer 35. One conductor layer 36 and one conductor layer 37 are connected to one conductor layer 35 in each of the spaces partitioned by the members SLT and SHE.

The member SLT divides the conductor layers 31 to 34. The core portion LI in the member SLT is provided along the member SLT. The second surface of the core portion LI is located between the conductor layer 34 (select gate line SGDTa) on one side and the conductor layer 35. The first surface of the core portion LI is located between the insulator layers 40 and 46. With this configuration, the core portion LI is connected to the conductor layer 30A. The core portion LI is used, for example, as a part of the source line SL. The spacer SP is provided between the core portion LI and the conductor layers 31 to 34. The core portion LI and the conductor layers 31 to 34 are separated and insulated from each other by the spacer SP. The core portion LI is formed, for example, of a semiconductor material such as silicon or a metal material. The member SLT may have a structure in which the entire member SLT is embedded by the insulating material of the spacer SP. Although not shown in FIG. 5, the core portion LI may include a barrier metal. That is, the core portion LI may have a structure in which a barrier metal covers the side surface and the first surface of a metal material containing, for example, tungsten.

A portion where each of the plurality of memory pillars MP intersects with the conductor layer 31 functions as the select transistor ST2. A portion where each of the plurality of memory pillars MP intersects with each conductor layer 32 functions as the memory cell transistor MT. A portion where each of the plurality of memory pillars MP intersects with each conductor layer 33 functions as the select transistor ST1. A portion where each of the plurality of memory pillars MP intersects with each conductor layer 34 functions as the select transistor STT1.

### 1.1.4.1.2.3 Cross-Sectional Structure of Memory Pillar

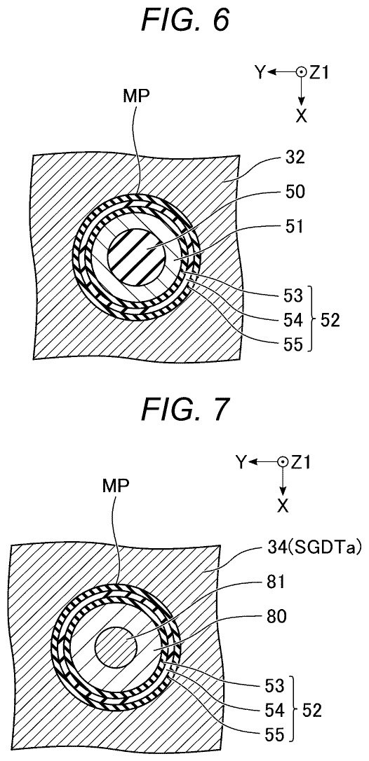

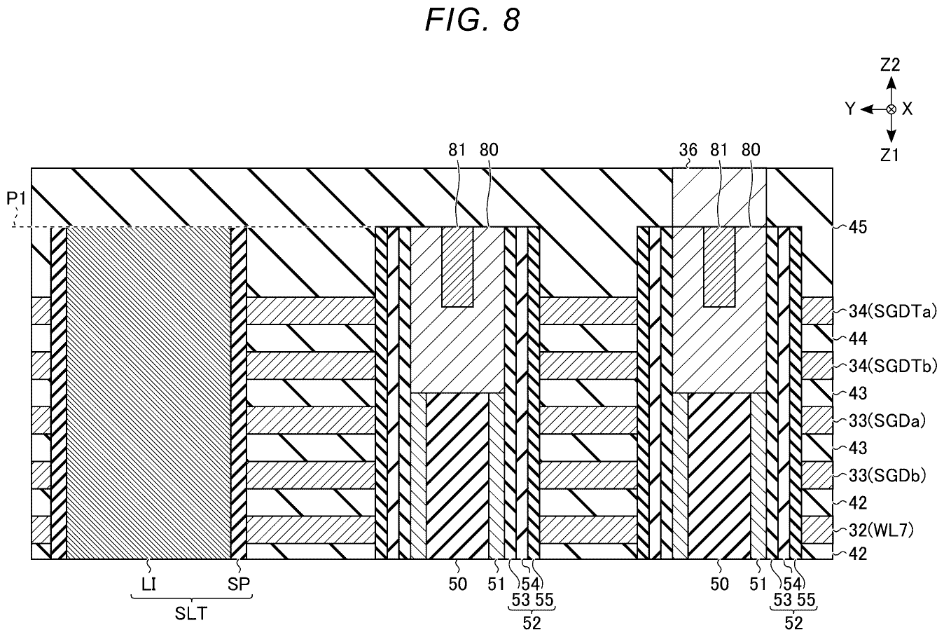

A structure of the memory pillar MP will be described with reference to FIGS. 6, 7, and 8. FIGS. 6 and 7 are cross-sectional diagrams showing an example of the cross-sectional structure of a memory pillar of the semiconductor memory device according to the embodiment. FIG. 6 illustrates a cross-sectional view taken along line VI-VI in FIG. 5. FIG. 7 illustrates a cross-sectional view taken along line VII-VII in FIG. 5. FIG. 8 is a cross-sectional diagram showing an example of the cross-sectional structure of the memory cell array of the semiconductor memory device according to the embodiment.

The laminate of films 52 includes a tunnel insulating film 53, a charge storage film 54, and a block insulating film 55. The tunnel insulating film 53 covers a side surface of the semiconductor film 51 except for a portion where the semiconductor film 51 and the conductor layer 30A are in contact with each other. The tunnel insulating film 53 also covers the side surface of the semiconductor portion 80. The charge storage film 54 covers a side surface of the tunnel insulating film 53. The block insulating film 55 covers a side surface of the charge storage film 54.

The tunnel insulating film 53 and the block insulating film 55 contain, for example, silicon oxide. The charge storage film 54 contains, for example, silicon nitride. The charge storage film 54 is a film that can store electric charges.

As shown in FIG. 8, a first surface of the semiconductor portion 80 is located, for example, between the conductor layer 33 (select gate line SGDa) on one side and the conductor layer 34 (select gate line SGDTb) on the other side. As described above, the semiconductor portion 80 is an n-type semiconductor to which impurities are added. With this configuration, an n-type semiconductor is disposed in the region corresponding to the select transistors STT1a and STT1b in the memory pillar MP. The semiconductor memory device 1 according to the embodiment generates a GIDL current using the select transistors STT1a and STT1b during an erase operation. In order to efficiently generate a GIDL current, the impurity concentration of the semiconductor portion 80 is preferably, for example, 1×10¹⁹ atoms/cm³ or more. The first surface of the semiconductor portion 80 may be located on the other side with respect to the conductor layer 34 (select gate line SGDTa) on the most one side and on one side with respect to the conductor layer 33 (select gate line SGDa) on the most one side. If the first surface of the semiconductor portion 80 is located on the other side with respect to the conductor layer 34 (select gate line SGDTa) on the most one side, an n-type semiconductor is formed in a region corresponding to at least one select transistor STT1 among the plurality of select transistors STT1. If the first surface of the semiconductor portion 80 is located on one side with respect to the conductor layer 33 (select gate line SGDa) on the most one side, the occurrence of malfunctions caused by fluctuations in the threshold voltage of the select transistor ST1 when the NAND string is selected is prevented.

With the configuration described as above, the semiconductor film 51 functions as, for example, a channel of each of the memory cell transistors MT0 to MT7 and the select transistors ST1a, ST1b, and ST2. The charge storage film 54 stores an amount of electric charge according to data stored in the memory cell transistor MT. On one side of the semiconductor film 51, the semiconductor portion 80 functions as, for example, a channel of each of the select transistors STT1a and STT1b.

The semiconductor memory device 1 causes a current to flow between the source line SL and the bit line BL via the memory pillar MP and the conductor layers 36 and 37 by turning on the memory cell transistors MT0 to MT7 and the select transistors STT1, ST1, and ST2.

The second surface of the memory pillar MP and the second surface of the member SLT are located at, for example, the same height P1. With this configuration, the height of the second surfaces of the semiconductor portion 80, the cap portion 81, the tunnel insulating film 53, the charge storage film 54, and the block insulating film 55 is equal to the height of the second surfaces of the spacer SP and the core portion LI, for example.

### 1.1.4.2 Overall Cross-Sectional Structure of Semiconductor Memory Device

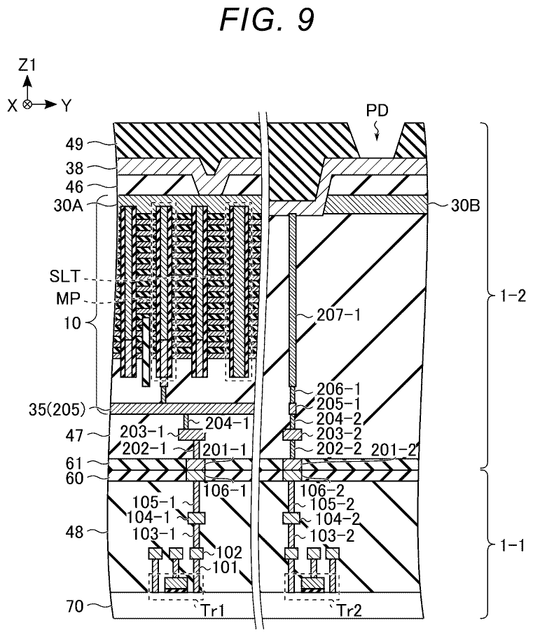

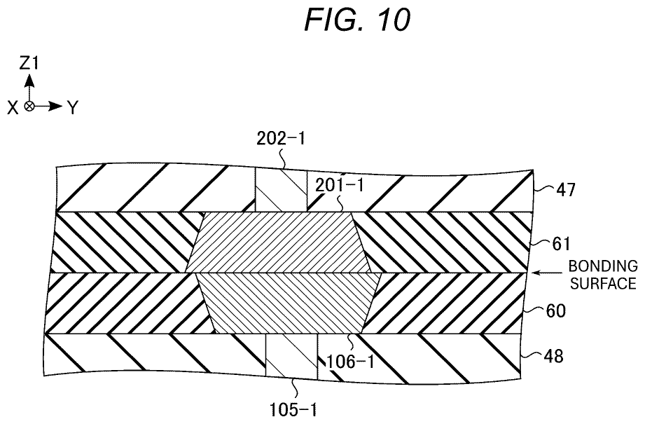

The overall cross-sectional structure of the semiconductor memory device 1 will be described with reference to FIG. 9. FIG. 9 is a cross-sectional diagram showing an example of a cross-sectional structure of the semiconductor memory device according to the embodiment. FIG. 9 shows the cross-sectional structure of a portion of the semiconductor memory device 1.

The semiconductor memory device 1 has a structure in which a circuit chip 1-1 and a memory chip 1-2 are bonded together.

### 1.1.4.2.1 Circuit Chip

First, a cross-sectional structure of the circuit chip 1-1 will be described.

The circuit chip 1-1 includes, for example, a semiconductor substrate 70, a plurality of conductor layers 101, 102, 103, 104, 105, and 106, insulator layers 48, and 60 that form a part of the peripheral circuit PERI. The semiconductor substrate 70 is, for example, made of a P-type semiconductor to which impurities are added.

Each of the plurality of conductor layers 101 to 106 functions, for example, as a columnar contact or wiring. The plurality of conductor layers 103 include conductor layers 103-1 and 103-2. The plurality of conductor layers 104 include conductor layers 104-1 and 104-2. The plurality of conductor layers 105 include conductor layers 105-1 and 105-2. The plurality of conductor layers 106 include conductor layers 106-1 and 106-2.

The insulator layer 48 is provided on a first surface of the semiconductor substrate 70. The insulator layer 48 contains, for example, silicon oxide. The plurality of conductor layers 101, 102, 103, 104, and 105 are provided in the insulator layer 48.

The peripheral circuit PERI is provided on the first surface of the semiconductor substrate 70. In FIG. 9, transistors Tr1 and Tr2 are shown as an example of the configuration provided in the peripheral circuit PERI. In the following description, when the transistors Tr1 and Tr2 are not distinguished from each other, the transistors Tr1 and Tr2 are simply referred to as transistors Tr. Each transistor Tr includes a gate insulating film, a gate electrode, and a source and a drain (not shown) provided on the semiconductor substrate 70.

On a first surface of each of the gate electrode, source, and drain of the transistor Tr1 and the gate electrode, source, and drain of the transistor Tr2, the plurality of conductor layers 101 are provided. Each of the plurality of conductor layers 102 is connected to a first surface of each of the plurality of conductor layers 101.

Each of the plurality of conductor layers 103 is connected to a first surface of the conductor layer 102 corresponding to that conductor layer 103 among the plurality of conductor layers 102. The conductor layers 103-1 and 103-2 are connected to the transistors Tr1 and Tr2, respectively.

The conductor layers 104-1 and 104-2 are connected to first surfaces of the conductor layers 103-1 and 103-2, respectively.

The conductor layers 105-1 and 105-2 are connected to first surfaces of the conductor layers 104-1 and 104-2, respectively. First surfaces of the plurality of conductor layers 105 are flush with a first surface of the insulator layer 48.

An insulator layer 60 is provided on the first surfaces of the insulator layer 48 and the plurality of conductor layers 105. The insulator layer 60 contains, for example, silicon oxide.

A plurality of conductor layer 106 are provided in the same layer as the insulator layer 60. The plurality of conductor layers 106 contain, for example, copper. The conductor layers 106-1 and 106-2 are connected to first surfaces of the conductor layers 105-1 and 105-2, respectively. First surfaces of the plurality of conductor layers 106 are flush with a first surface of the insulator layer 60. The plurality of conductor layers 106 function as a plurality of connection pads for electrically connecting the circuit chip 1-1 and the memory chip 1-2 to each other. The connection pads are also referred to as bonding pads.

### 1.1.4.2.2 Memory Chip

A cross-sectional structure of the memory chip 1-2 will be described with reference to FIG. 9.

The memory chip 1-2 includes, for example, a plurality of conductor layers 201, 202, 203, 204, 205, 206, and 207, a conductor layer 38, insulator layers 46, 47, 49, and 61, and the memory cell array 10.

Each of the plurality of conductor layers 201 to 207 functions, for example, as a columnar contact or wiring. The plurality of conductor layers 201 includes conductor layers 201-1 and 201-2. The plurality of conductor layers 202 includes conductor layers 202-1 and 202-2. The plurality of conductor layers 203 includes conductor layers 203-1 and 203-2. The plurality of conductor layers 204 include conductor layers 204-1 and 204-2. The plurality of conductor layers 205 include conductor layers 35 (205) and 205-1. Each of the plurality of conductor layers 206 includes a conductor layer 206-1. Each of the plurality of conductor layers 207 includes a conductor layer 207-1.

In the memory chip 1-2, an insulator layer 61 is provided on a first surface of the circuit chip 1-1. The insulator layer 61 contains, for example, silicon oxide.

The plurality of conductor layers 201 are provided on the same layer as the insulator layer 61. The plurality of conductor layers 201 contain, for example, copper. The conductor layers 201-1 and 201-2 are connected to first surfaces of the conductor layers 106-1 and 106-2, respectively. Second surfaces of the plurality of conductor layers 201 are flush with a second surface of the insulator layer 61.

The plurality of conductor layers 201 function as a plurality of connection pads for electrically connecting the circuit chip 1-1 and the memory chip 1-2 to each other. With the configuration described as above, the circuit chip 1-1 and the memory chip 1-2 are electrically connected to each other by the plurality of conductor layers 106 and 201.

The insulator layer 47 is provided on first surfaces of the insulator layer 61 and the plurality of conductor layers 201. In the insulator layer 47, for example, the plurality of conductor layers 202 to 206, a portion of the plurality of conductor layers 207, and a portion of the memory cell array 10 are provided.

The memory cell array 10 is provided such that, in the Z-direction, the conductor layer 30A is disposed on the other side and the conductor layer 35 (205) is disposed on one side.

The conductor layer 202-1 is provided on a first surface of the conductor layer 201-1. The conductor layer 203-1 is connected to a first surface of the conductor layer 202-1. The conductor layer 204-1 is connected to a first surface of the conductor layer 203-1. A first surface of the conductor layer 204-1 is connected to the conductor layer 35 (205). With the configuration described as above, the conductor layer 35 (205) and the transistor Tr1 are configured to be connectable to each other. That is, the bit line BL of memory cell array 10 and the peripheral circuit PERI are connected to each other.

The conductor layer 202-2 is provided on a first surface of the conductor layer 201-2. The conductor layer 203-2 is provided on a first surface of the conductor layer 202-2. The conductor layer 204-2 is provided on a first surface of the conductor layer 203-2. The conductor layer 205-1 is provided on a first surface of the conductor layer 204-2. The conductor layer 206-1 is provided on a first surface of the conductor layer 205-1. The conductor layer 207-1 is provided on a first surface of the conductor layer 206-1. The conductor layer 207-1 extends in the Z-direction. A portion on the other side of conductor layer 207-1 protrudes from the insulator layer 47. The conductor layer 207-1 functions, for example, as a columnar contact.

On the first surface of the insulator layer 47 except for the portion of the first surface surrounding the conductor layer 207-1 protruding from the insulator layer 47, for example, a conductor layer 30B is provided. The conductor layer 30B is provided in the same layer as the conductor layer 30A. That is, the conductor layer 30B is provided in a portion different from the portion where the memory cell array 10 and the conductor layer 207-1 are provided.

The insulator layer 46 is provided on the portion of the first surface of the conductor layer 30A of the memory cell array 10 and on the first surface of the conductor layer 30B.

On the first surface of the insulator layer 46, on the portion of the first surface of the conductor layer 30A where the insulator layer 46 is not provided, on the first surface of the conductor layer 207-1, and on the portion of the first surface of the insulator layer 47 surrounding the conductor layer 207-1, a conductor layer 38 is provided. The conductor layer 38 functions as a wiring layer extending in the Y-direction, for example. The conductor layer 38 contains, for example, aluminum. Although not shown, a spacer is provided on the side surface of the conductor layer 30B adjacent to the conductor layer 38 provided on the first surface portion of the insulator layer 47 surrounding the conductor layer 207-1, and the conductor layer 38 and the conductor layer 30B are electrically isolated by the spacer.

The conductor layer 38 connected to the conductor layer 207-1 includes, for example, a portion exposed to the first surface of the semiconductor memory device 1 above the insulator layer 46. The portion functions as an electrode pad PD. The electrode pad PD functions as a lead-out pad for connecting to an external device of the semiconductor memory device 1. With this configuration described as above, for example, the electrode pad PD and the transistor Tr2 are configured to be connectable to each other via the conductor layers 101 to 106 and 201 to 207. That is, the electrode pad PD and the peripheral circuit PERI are connected to each other.

Although not shown, a portion of the conductor layer 38 in contact with the conductor layer 30A is configured to be connected to the peripheral circuit PERI of the circuit chip 1-1, for example, by the same configuration as the conductor layers 201 to 207. With this configuration, the conductor layer 30A and the peripheral circuit PERI are configured to be connectable to each other via the conductor layers 38, 101 to 106, and 201 to 207.

Although not shown, each of the conductor layers 31 to 34 of the memory cell array 10 is connected to the peripheral circuit PERI of the circuit chip 1-1, for example, by the same configuration as the conductor layers 201 to 205 and the like. With this configuration, each of the conductor layers 31 to 34 and the peripheral circuit PERI are configured to be connectable to each other via the configurations of the conductor layers 101 to 106, 201 to 205, and the like.

The insulator layer 49 is stacked on a portion on the other side of the semiconductor memory device 1, except for the portion where the electrode pad PD is provided. The insulator layer 49 functions, for example, as a passivation film.

### 1.1.4.2.3 Cross-Sectional Structure of Connection Pad

A cross-sectional structure of the connection pad will be described with reference to FIG. 10. FIG. 10 is a cross-sectional diagram showing an example of the cross-sectional structure of the connection pad of the semiconductor memory device according to the embodiment.

In the following, the portion where the conductor layer 106-1 and the conductor layer 201-1 are connected will be described, but the same applies to the portions where each of the other conductor layers 106 and the conductor layer 201 corresponding to that conductor layer 106 are connected.

On the bonding surface where the circuit chip 1-1 and the memory chip 1-2 are bonded together, an area of the conductor layer 106-1 and an area of the conductor layer 201-1 are, for example, equal. When the conductor layers 106-1 and 201-1 are made of copper, the conductor layers 106-1 and 201-1 may become integrated to make it difficult to check a copper boundary between the conductor layers 106-1 and 201-1. However, for example, the bonding can be confirmed by the distortion of the bonded shape of the conductor layers 106-1 and 201-1 due to the misalignment of the bonding positions. In addition, for example, the bonding can be confirmed by checking the misalignment of the copper barrier metal. That is, the bonding can be confirmed by checking the occurrence of discontinuous parts on the side surfaces.

When the conductor layers 106-1 and 201-1 are formed by the damascene method, a side surface of each of the conductor layers 106-1 and 201-1 has a taper shape. With this configuration, a side wall of the conductor layer 106-1 and a side wall of the conductor layer 201-1 are not aligned in a straight line. Therefore, a cross-sectional shape along the Z-direction at the portion where the conductor layers 106-1 and 201-1 are bonded together has a non-rectangular shape.

Furthermore, when the conductor layers 106-1 and 201-1 are bonded together, a structure, in which a barrier metal covers a first surface, second surface, and side surfaces of the copper that forms the conductor layers 106-1 and 201-1, is formed. In contrast, in a typical wiring layer using copper, an insulator layer (such as silicon nitride or silicon carbide containing nitrogen) that has a function of preventing oxidation of copper is provided on the upper surface of the copper, and no barrier metal is provided. Therefore, even if no misalignment of the boding positions occurs, it is possible to distinguish the bonding from a general wiring layer.

### 1.2 Manufacturing Method

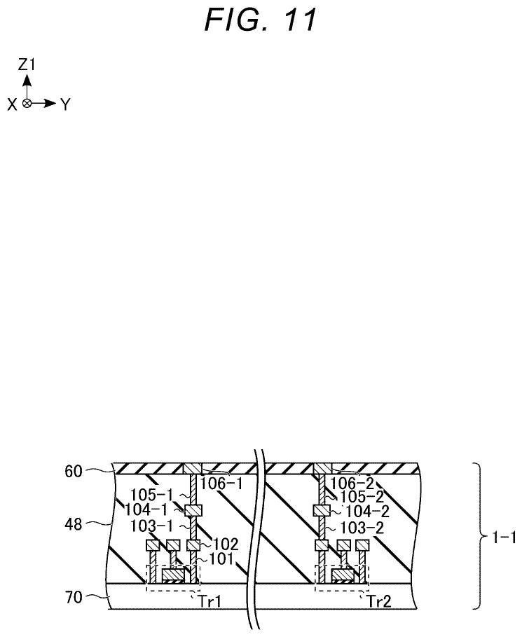

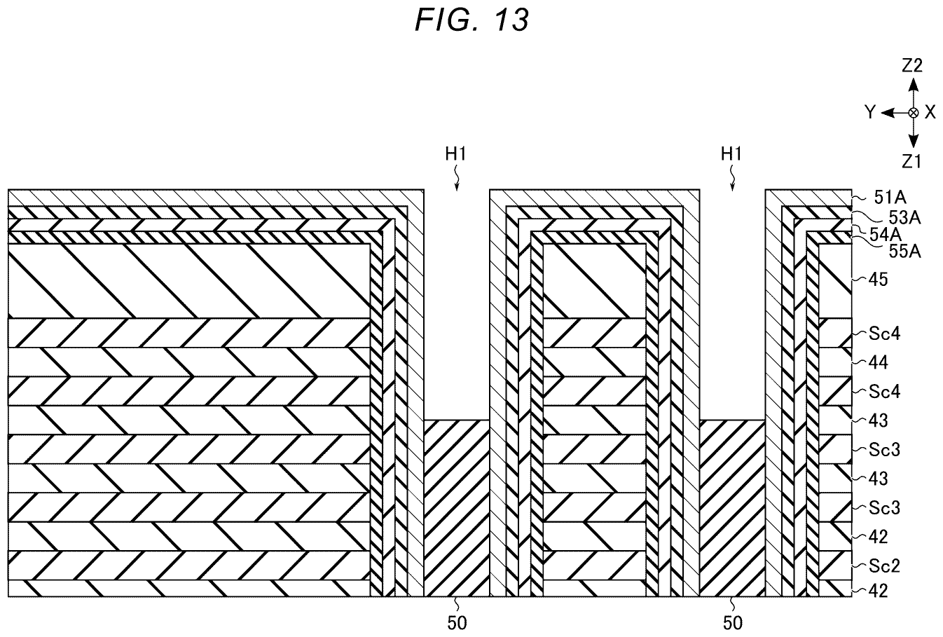

A method for manufacturing the semiconductor memory device 1 according to an embodiment will be described with reference to FIGS. 11 to 22. FIGS. 11 to 22 are cross-sectional diagrams for illustrating an example of process steps of the method for manufacturing the semiconductor memory device according to the embodiment. FIGS. 11, 12, 15, 16, 21, and 22 show the region corresponding to FIG. 9. FIGS. 13, 14, and 17 to 20 show the region corresponding to FIG. 8.

First, as shown in FIG. 11, a circuit chip 1-1 is formed.

Next, a memory chip 1-2 portion is formed as described below.

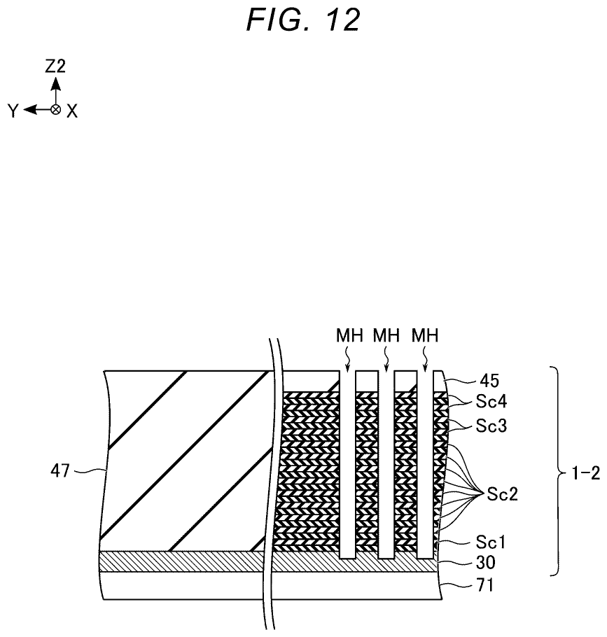

First, on a second surface of a semiconductor substrate 71, a conductor layer 30, a sacrifice layer Sc1 corresponding to the conductor layer 31, a plurality of sacrifice layers Sc2 corresponding to a plurality of conductor layers 32, a plurality of sacrifice layers Sc3 corresponding to a plurality of conductor layers 33, a plurality of sacrifice layers Sc4 corresponding to a plurality of conductor layers 34, and insulator layers 40 to 45 and 47 are formed. Furthermore, as shown in FIG. 12, a plurality of memory holes MH corresponding to a plurality of memory pillars MP are formed by anisotropic etching using a mask. The anisotropic etching in this step is, for example, Reactive Ion Etching (RIE). Then, the mask is removed.

Next, as shown in FIG. 13, in the plurality of memory holes MH and on a second surface of the insulator layer 45, a semiconductor layer 51A, an insulator layer 53A, a charge storage layer 54A, and an insulator layer 55A are formed. Furthermore, a core member 50 is formed corresponding to each of the plurality of memory holes MH. More specifically, on a side surface and bottom surface of the memory hole MH and on the second surface of the insulator layer 45, the insulator layer 55A, the charge storage layer 54A, and the insulator layer 53A are formed in this order. After that, for example, a part of the insulator layer 55A, the charge storage layer 54A, and the insulator layer 53A on the other side of the memory hole MH is removed. Furthermore, the semiconductor layer 51A is formed on a front surface of the insulator layer 53A and on the removed part. The semiconductor layer 51A is in contact with the conductor layer 30. Then, the core member 50 is formed so as to be embedded in the portion of memory hole MH in which the semiconductor layer 51A, the insulator layer 53A, the charge storage layer 54A, and the insulator layer 55A are formed. A second surface of the core member 50 is located between the sacrifice layer Sc3 on one side and the sacrifice layer Sc4 on the other side, as shown in FIG. 13. Through the above steps, each of a plurality of holes H1 surrounded by the second surface of the core member 50 and the semiconductor layer 51A are formed on one side of the core member 50.

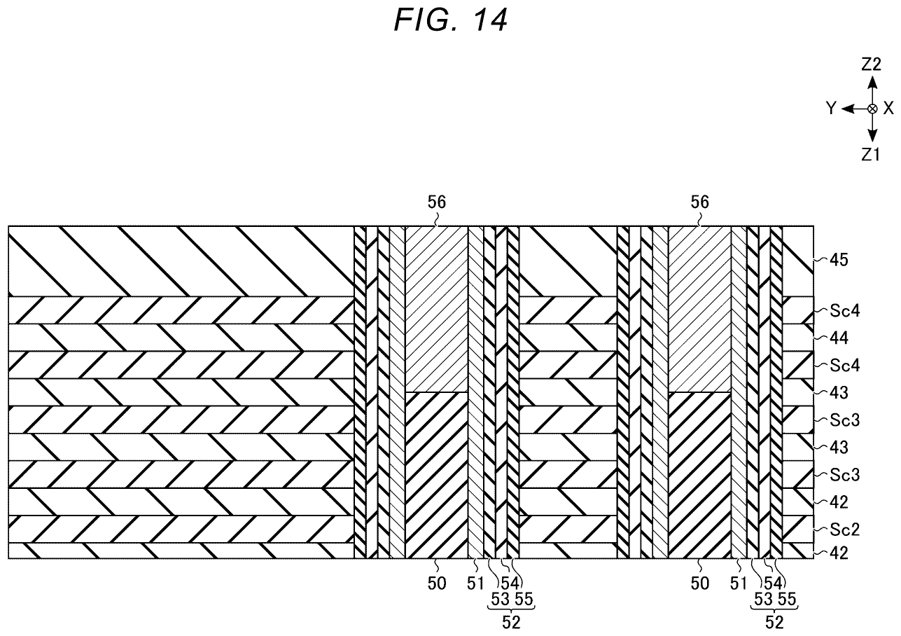

Then, a semiconductor is formed in the plurality of holes H1 and on a second surface of the semiconductor layer 51A so as to fill the plurality of holes H1 formed as described above. Furthermore, as shown in FIG. 14, a portion on one side of the structure corresponding to the memory chip 1-2 formed as described above is removed by, for example, a chemical mechanical polishing (CMP) process. As a result, a semiconductor film 51, a tunnel insulating film 53, a charge storage film 54, a block insulating film 55, and a semiconductor 56 are formed corresponding to each memory pillar MP. The semiconductor 56 is the portion of the semiconductor formed by filling the hole H1 as described above. The semiconductor 56 is formed of, for example, amorphous silicon to which no impurities are added.

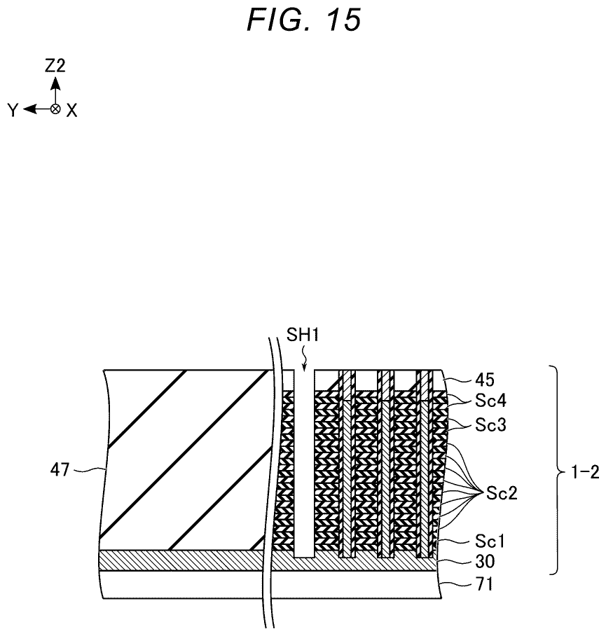

Then, as shown in FIG. 15, a plurality of slits SH1 are formed. More specifically, regions where a plurality of members SLT are to be formed are removed by anisotropic etching using a mask including openings corresponding to the plurality of members SLT. As a result, the plurality of slits SH1 are formed. The anisotropic etching in this step is, for example, RIE. Then, the mask is removed.

The sacrifice layers Sc1 to Sc4 are replaced with the conductor layers 31 to 34, respectively. More specifically, for example, the sacrifice layers Sc1 to Sc4 are selectively removed through the plurality of slits SH1 by wet etching using hot phosphoric acid. Then, a conductor is filled in the space from which the sacrifice layer Sc1 and the plurality of sacrifice layers Sc2, Sc3, and Sc4 are removed. As a result, the conductor layers 31 to 34 are formed. In the following, the process of replacing the sacrifice layers Sc1 to Sc4 with the conductor layers 31 to 34 as described above will be simply referred to as a replacement process.

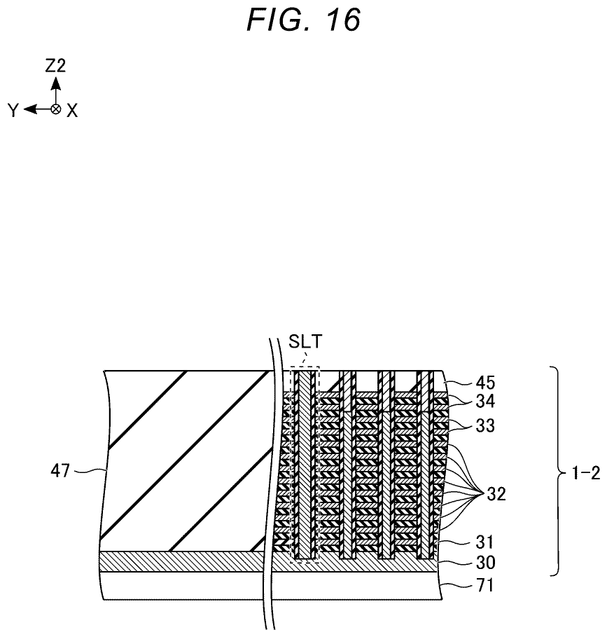

Next, as shown in FIG. 16, the plurality of members SLT are formed. More specifically, for example, spacers SP are formed so as to cover the side surfaces and bottom surfaces of the plurality of slits SH1. Furthermore, after removing the spacers SP formed on the bottom surfaces of the slits SH1, a core portion LI is formed so as to fill the plurality of slits SH1 in which the spacers SP are formed.

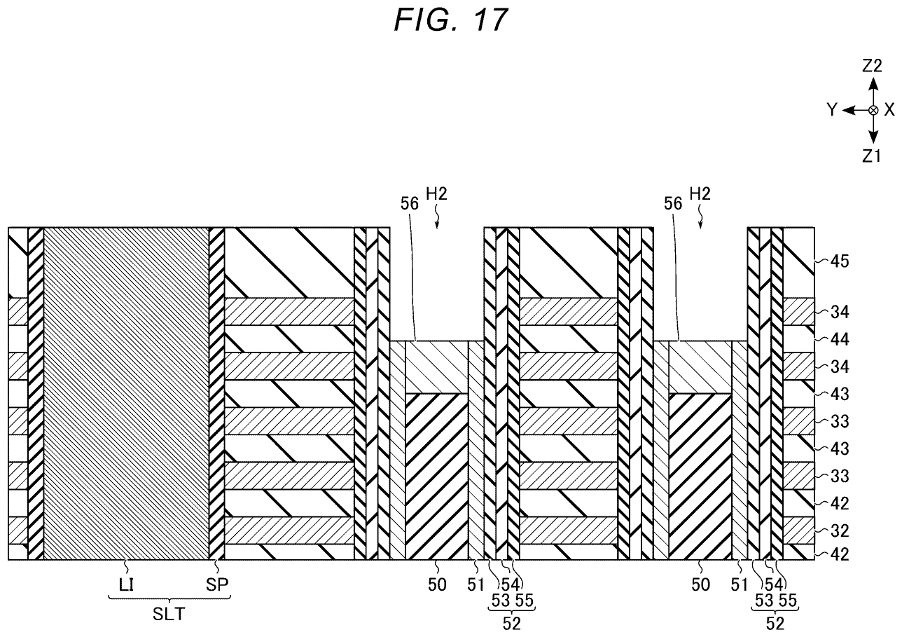

Then, as shown in FIG. 17, a portion on one side of the semiconductor film 51 and a portion on one side of the semiconductor 56 are removed. As a result, a plurality of holes H2, which are surrounded by a second surface of the semiconductor film 51, a second surface of the semiconductor 56, and a side surface of the tunnel insulating film 53, are formed.

Then, for example, a semiconductor 80A is formed so as to conformally cover the side surfaces and bottom surfaces of the holes H2 and a second surface of a structure corresponding to the memory chip 1-2 formed as described above. The semiconductor 80A is formed in a liner shape on the structure. That is, in the course of forming the semiconductor 80A, a surface topology of the structure including the holes H2 is approximately kept on a front surface of the semiconductor 80A, and the holes H2 are covered by the semiconductor 80A conformally on the surfaces of the holes H2, not to be filled with the semiconductor 80A. The semiconductor 80A is amorphous n-type semiconductor silicon to which impurities are added, similar to the semiconductor portion 80.

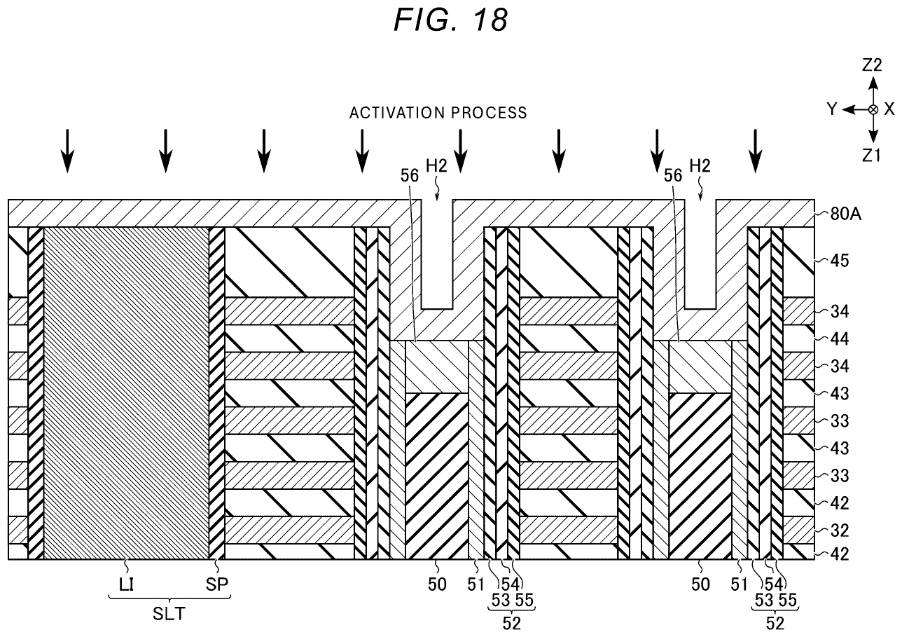

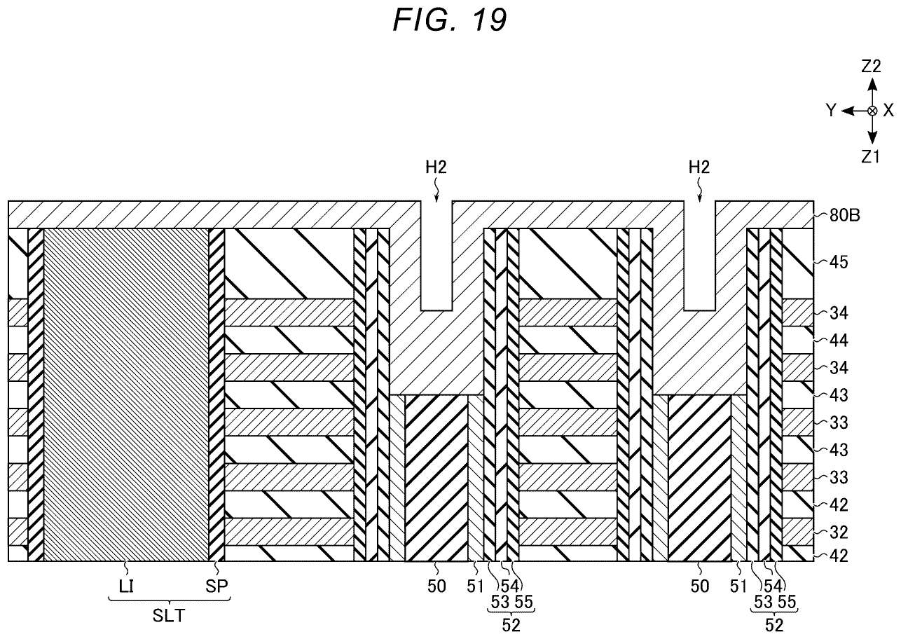

As shown in FIG. 18, an activation process is performed on the semiconductor 80A to which the impurities are added. The activation process is, for example, a laser spike annealing (LSA) process. Through this activation process, the semiconductor 80A is activated, and as shown in FIG. 19, the semiconductor 80A is integrated with the semiconductor 56 and the portion of the semiconductor film 51 on one side of the core member 50 to form a semiconductor 80B containing polysilicon. By the activation process, for example, impurities become substantially uniformly distributed in the semiconductor 80B. The concentration of the impurities in the semiconductor 80B is made equal to the concentration of the impurities in the semiconductor portion 80.

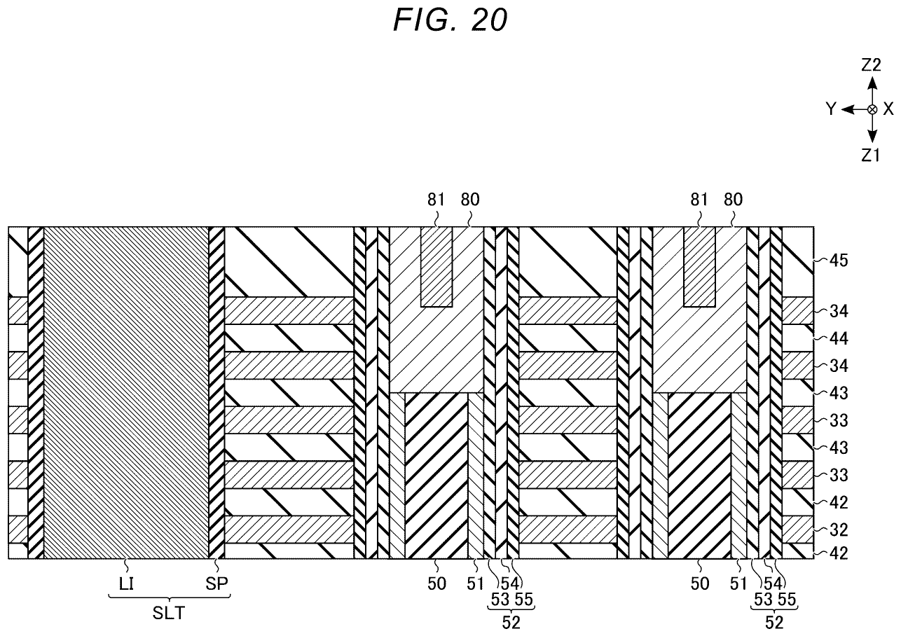

Next, as shown in FIG. 20, the semiconductor portion 80 and a cap portion 81 are formed. More specifically, a conductor is formed on a second surface of the semiconductor 80B so as to fill the plurality of holes H2. The conductor is, for example, the same conductive material as that of the cap portion 81. Then, for example, by the CMP process, a portion on one side of the structure corresponding to the memory chip 1-2 formed as described above is removed. As a result, the semiconductor portion 80 and the cap portion 81 of each memory pillar MP are formed.

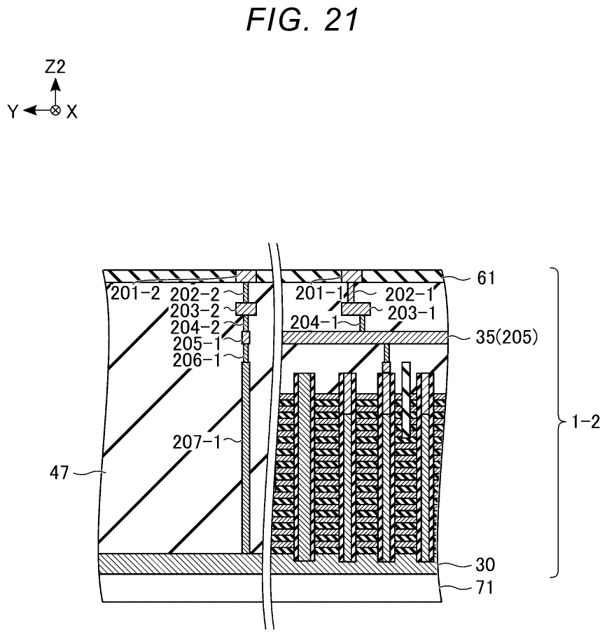

Then, as shown in FIG. 21, conductor layers 201 to 207, a plurality of members SHE, and an insulator layer 61 are formed.

Through the steps described above, the memory chip 1-2 portion is formed.

The circuit chip 1-1 and the memory chip 1-2 portion are bonded together by a bonding process. More specifically, a plurality of conductor layers 106 functioning as connection pads in the circuit chip 1-1 and a plurality of conductor layers 201 functioning as connection pads in the memory chip 1-2 are arranged to face each other. Furthermore, the facing connection pads are bonded to each other by heat treatment. After that, the semiconductor substrate 71 is removed by, for example, a CMP process.

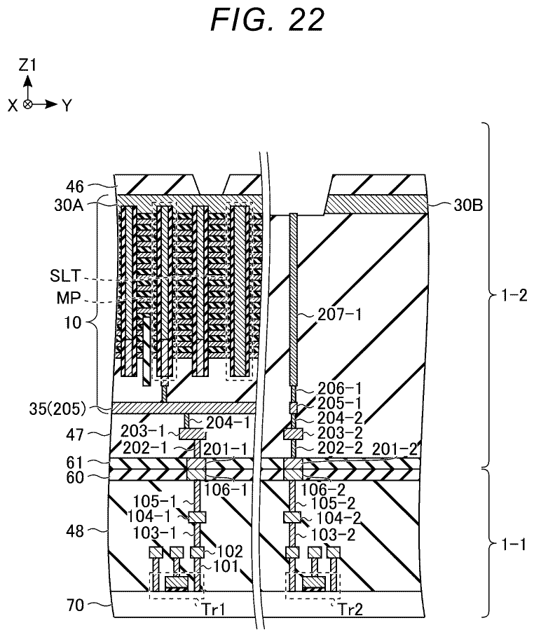

Next, an insulator layer 46 is formed on the first surface of the conductor layer 30. As shown in FIG. 22, for example, a portion of the conductor layer 30 and portions of the insulator layers 46 and 47 are removed so that a portion on the other side of the conductor layer 207 is exposed. As a result, a portion of a first surface of the insulator layer 47 is exposed. The conductor layer 30 is divided into conductor layers 30A and 30B. As a result, the conductor layers 30A and 30B are electrically insulated from each other. Furthermore, in the region corresponding to the memory cell array 10, a portion of the insulator layer 46 is removed so that a portion of a first surface of the conductor layer 30A is exposed.

Then, a conductor layer 38 and an insulator layer 49 are formed.

Through the manufacturing steps described as above, the semiconductor memory device 1 is manufactured.

The manufacturing steps described above are merely an example, and other processing steps may be inserted between the respective manufacturing steps, or the order of the manufacturing steps may be changed. For example, since the circuit chip 1-1 and the memory chip 1-2 portion are formed using different semiconductor substrates 70 and 71, the steps of forming the circuit chip 1-1 shown in FIG. 11 and the steps of forming the memory chip 1-2 shown in FIGS. 12 to 21 may be performed in parallel.

### 1.3 Effects and Advantages

According to the embodiment, the reliability of the semiconductor memory device 1 can be improved. The effects or advantages of the embodiment will be described below.

The semiconductor memory device 1 according to the embodiment includes the semiconductor substrate 70 and the memory cell array 10. The memory cell array 10 includes the source line SL, the plurality of word lines WL provided on one side of the source line SL, the select gate line SGDTa provided on one side of the plurality of word lines WL, and the memory pillar MP. The memory pillar MP includes the core member 50, the semiconductor film 51, the cap portion 81, the semiconductor portion 80, and the laminate of films 52. The core member 50 extends from a position on the other side of the plurality of word lines WL to at least a position on one side of the plurality of word lines WL. The semiconductor film 51 is provided on a side surface of the core member 50. The cap portion 81 is provided on one side with respect to the core member 50. The semiconductor portion 80 is an n-type semiconductor containing impurities. The semiconductor portion 80 covers the side surface and the first surface of the cap portion 81. The semiconductor portion 80 is electrically connected to the semiconductor film 51. The laminate of films 52 covers the side surface of the semiconductor film 51 and the side surface of the semiconductor portion 80. With the configuration described as above, the occurrence of variations in impurity concentration on one side of the plurality of memory pillars MP can be prevented. Furthermore, the occurrence of short circuits between wiring layers caused by fluorine gas is prevented. Therefore, according to the embodiment, the reliability of the semiconductor memory device 1 can be improved.

The above effects or advantages will be described using a comparative example in which the memory pillar does not include any cap portion. In the comparative example, the semiconductor portion containing impurities is provided, for example, so as to be embedded in the entire space on one side of the core member and the semiconductor film, instead of being provided in a liner shape. The impurities are introduced from the semiconductor portion into a portion on one side of the semiconductor film of the memory pillar. However, in this case, since the impurities are introduced from the semiconductor portion embedded in the entire space to the semiconductor film, the diffusion length of the impurities becomes longer. As a result, controlling the impurity concentration of semiconductor films may become difficult. Therefore, variations in impurity concentration may occur in the plurality of memory pillars.

According to the embodiment, when forming the semiconductor portion 80, as described with reference to FIGS. 18 and 19, for example, the semiconductor 80A containing impurities is integrated with the portion of the semiconductor 56 and the semiconductor film 51 on one side of the core member 50 by the LSA process. Furthermore, by forming the semiconductor 80A in a liner shape, the impurities in the semiconductor 80A can be activated uniformly throughout the semiconductor 80B by the LSA process. According to such a process, compared to the case where the memory pillar does not include a cap portion as in the comparative example, the semiconductor 80A is formed in a liner shape, so that the diffusion length of impurities can be reduced. As a result, the occurrence of concentration variations of impurities in the channel of the select transistor STT1 can be prevented. Therefore, when the GIDL current is generated in an erase operation, the occurrence of a malfunction of the select transistor STT1 is prevented.

In the replacement process, the wiring layer is formed by a CVD method using, for example, tungsten hexafluoride (WF₆) as a film forming gas. The gas contains fluorine. As a result, the formed wiring layer may be a layer containing fluorine. When heat treatment or the like is performed on a structure including such a wiring layer, fluorine gas may be generated from the wiring layer. Such generation of fluorine gas is known to cause short circuits between wiring layers.

As described above, in the comparative example, the impurities on one side of the semiconductor film is introduced from the semiconductor portion provided to be embedded in the entire space. In such a case, localized treatment of the semiconductor portion may make it difficult to introduce impurities into the semiconductor film. Therefore, in the comparative example, impurities are introduced into the semiconductor film by overall heat treatment of the entire structure formed. In such a case, if the introduction of the impurities into the semiconductor film is performed after the replacement process, fluorine gas may be generated from the wiring layer by the heat treatment after the replacement process. From the matters described above, in the manufacturing steps of the comparative example, in order to prevent the generation of fluorine gas from the wiring layer, it is considered to perform the replacement process after introducing impurities into the semiconductor film. However, in this case, the concentration distribution of impurities within the semiconductor film may change due to heating during the replacement process. As described above, the comparative example has a problem in that a trade-off relationship occurs between the quality of the wiring layer and the quality of the memory pillar.

According to the embodiment, the semiconductor portion 80 is formed using the LSA process. That is, in the embodiment, a portion on one side of the structure in which the semiconductor 80A is formed is locally processed. Therefore, even if the LSA process is performed after the replacement process, the generation of fluorine gas from the wiring layer is prevented. In the embodiment, since the LSA process is performed after the replacement process, the impurity concentration near the semiconductor portion 80 does not change due to the replacement process. From the matters described above, according to the embodiment, the impurity concentration on one side of the memory pillar MP can be controlled and the generation of fluorine gas from the wiring layer can be prevented. Therefore, the occurrence of operational defects in the semiconductor memory device 1 can be prevented.

From the matters described above, the reliability of the semiconductor memory device 1 can be improved.

### 2. Modifications

The embodiment described above can be modified in various ways. Below, a semiconductor memory device according to modifications will be described.

### 2.1 First Modification

In the embodiment described above, second surfaces of the plurality of memory pillars MP and a second surface of a member SLT are located at the same height, but the embodiment is not limited thereto. The second surface of the member SLT may be located, for example, on one side of the second surfaces of the plurality of memory pillars MP. In the following, the configuration of the semiconductor memory device 1 according to the first modification will be mainly described on the points that are different from the configuration of the semiconductor memory device according to the embodiment.

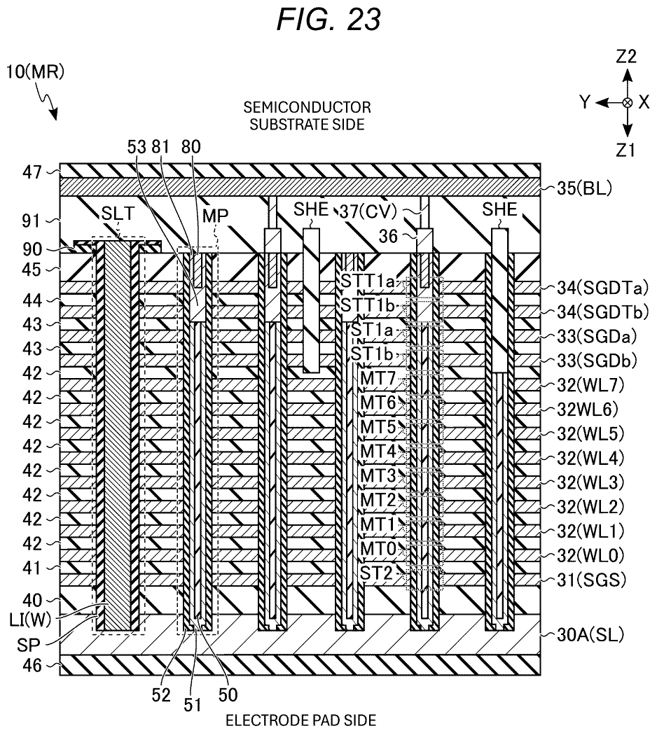

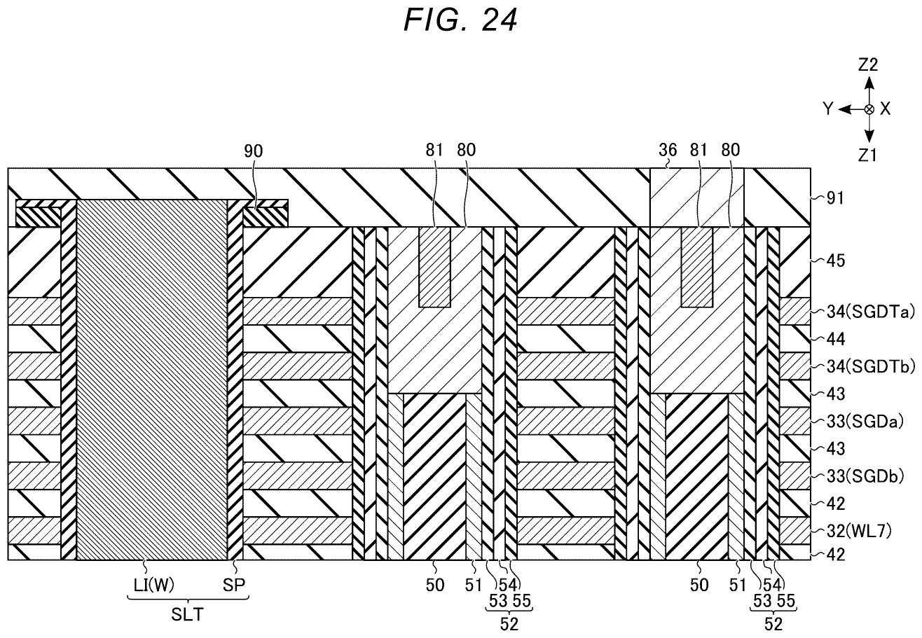

A structure of the memory cell array 10 in the semiconductor memory device 1 according to the first modification will be described with reference to FIGS. 23 and 24. FIG. 23 is a cross-sectional diagram showing an example of a cross-sectional structure of a memory cell array of the semiconductor memory device according to the first modification. FIG. 23 corresponds to the region shown in FIG. 5 of the embodiment. FIG. 24 is a cross-sectional diagram showing an example of the cross-sectional structure of the memory cell array of the semiconductor memory device according to the first modification. FIG. 24 corresponds to the region shown in FIG. 8 of the embodiment.

The memory cell array 10 according to the first modification further includes insulator layers 90 and 91.

The second surface of the insulator layer 45 is located at, for example, the same height as the second surface of the memory pillar MP.

A second surface of the core portion LI is located on one side with respect to the insulator layer 45 and the memory pillar MP. In the first modification, the core portion LI is made of a metal material including tungsten or the like.

An insulator layer 90 is provided on the second surface of the insulator layer 45 so as to surround a spacer SP when viewed from above. A second surface of the insulator layer 90 is located on the other side with respect to the second surface of the core portion LI.

The spacer SP covers a side surface of the core portion LI and to cover the second surface of the insulator layer 90.

The insulator layer 91 is provided between the insulator layer 45 and the conductor layer 35.

In the configuration described as above, the core portion LI, the spacer SP, and the insulator layer 90 function as, for example, the member SLT.

Furthermore, with the configuration described as above, a width in the Y-direction of a portion of the member SLT on one side of the insulator layer 45 is wider than a width in the Y-direction of the portion of the member SLT on the other side of that portion. Although not shown, a width in the X-direction of a portion on one side of the member SLT is wider than a width in the X-direction of a portion of the member SLT on the other side of that portion.

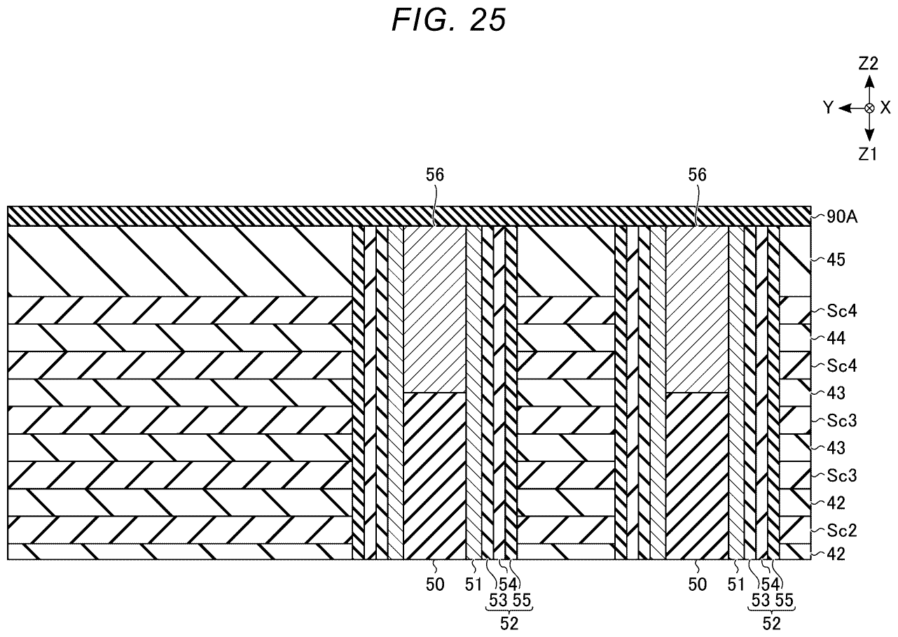

Next, a method for manufacturing the semiconductor memory device 1 according to the first modification will be described with reference to FIGS. 25, 26, and 27. FIGS. 25, 26, and 27 are cross-sectional diagrams for illustrating an example of process steps of the method for manufacturing the semiconductor memory device according to the first modification.

After the step described with reference to FIG. 14 of the embodiment, as shown in FIG. 25, an insulator 90A is formed on a second surface of each of the insulator layer 45, the semiconductor film 51, the tunnel insulating film 53, the charge storage film 54, the block insulating film 55, and the semiconductor 56.

Next, similarly to the step described with reference to FIG. 15 of the embodiment, a plurality of slits SH1 are formed. Furthermore, the conductor layers 31 to 34 are formed by a replacement process from the slits SH1.

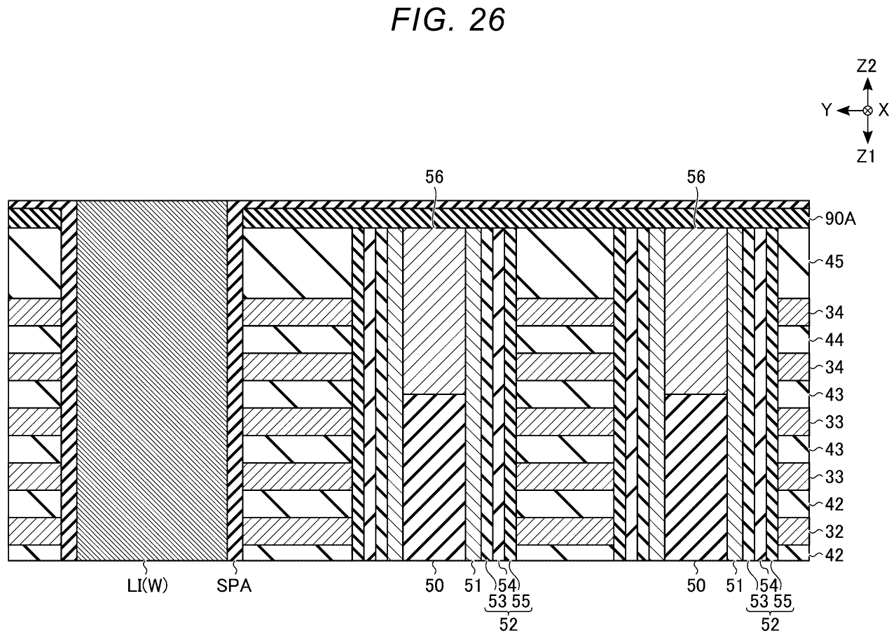

Then, an insulator SPA is formed so as to cover the side surfaces and bottom surfaces of the plurality of slits SH1 and a second surface of the insulator 90A. After removing the insulator SPA formed on the bottom surface of the slit SH1, as shown in FIG. 26, the core portion LI is formed so as to fill the plurality of slits SH1 in which the insulator SPA is formed.

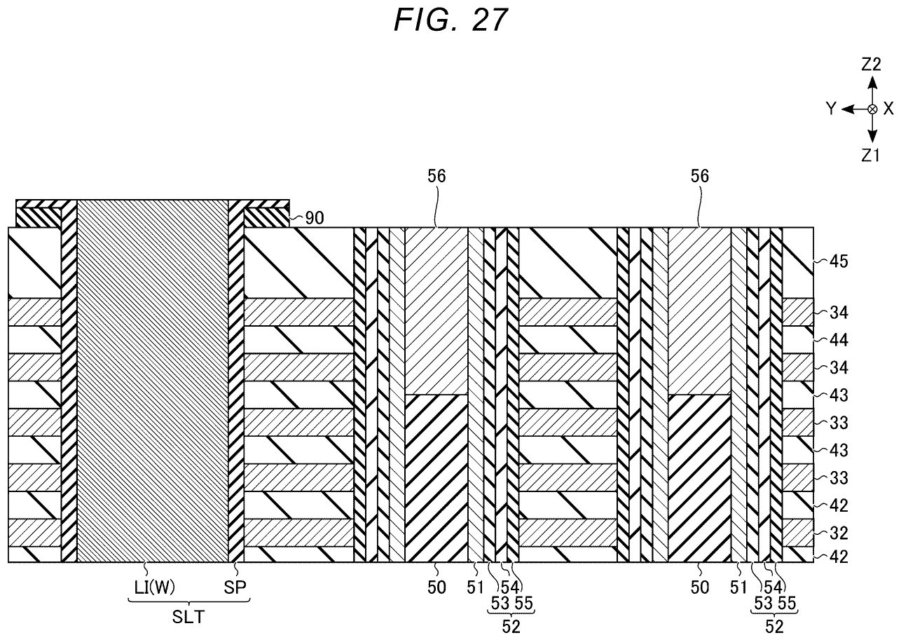

After that, the portion of the insulator SPA and the portion of the insulator 90A are removed by etching using a mask, so that the member SLT including the insulator layer 90, the spacers SP and the core portion LI is formed, as shown in FIG. 27.

Through the steps described above, the semiconductor memory device 1 according to the first modification is manufactured.

The first modification also achieves the same effects or advantages as the embodiment.

### 2.2 Second Modification

In the embodiment and first modification described above, the case in which the first surface of the semiconductor portion 80 is provided between the conductor layer 33 (select gate line SGDa) on one side and the conductor layer 34 (select gate line SGDTb) on the other side has been described, but the embodiment is not limited thereto. The first surface of the semiconductor portion 80 may be located, for example, on one side of the first surface of the conductor layer 34 (select gate line SGDTb) on the other side. In the following, the configuration of the semiconductor memory device 1 according to the second modification, which is different from the configuration of the semiconductor memory device according to the embodiment, will be described.

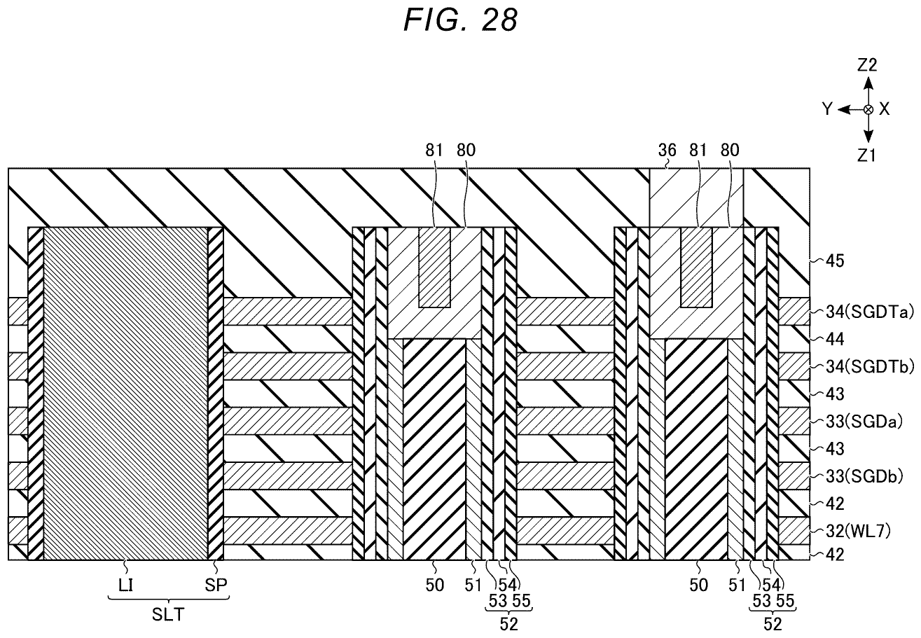

A structure of the memory cell array 10 in the semiconductor memory device 1 according to the second modification will be described with reference to FIG. 28. FIG. 28 is a cross-sectional diagram showing an example of a cross-sectional structure of a memory cell array of the semiconductor memory device according to the second modification. FIG. 28 corresponds to the region shown in FIG. 8 of the embodiment.

The second surfaces of the core member 50 and the semiconductor film 51 are located on one side of the first surface of the conductor layer 34 (select gate line SGDTb) on the other side. The first surface of the semiconductor portion 80, similar to the second surfaces of the core member 50 and the semiconductor film 51, is located on one side of the first surface of the conductor layer 34 (select gate line SGDTb) on the other side. In the example shown in FIG. 28, the second surfaces of the core member 50 and the semiconductor film 51, and the first surface of the semiconductor portion 80 are located between two conductor layers 34.

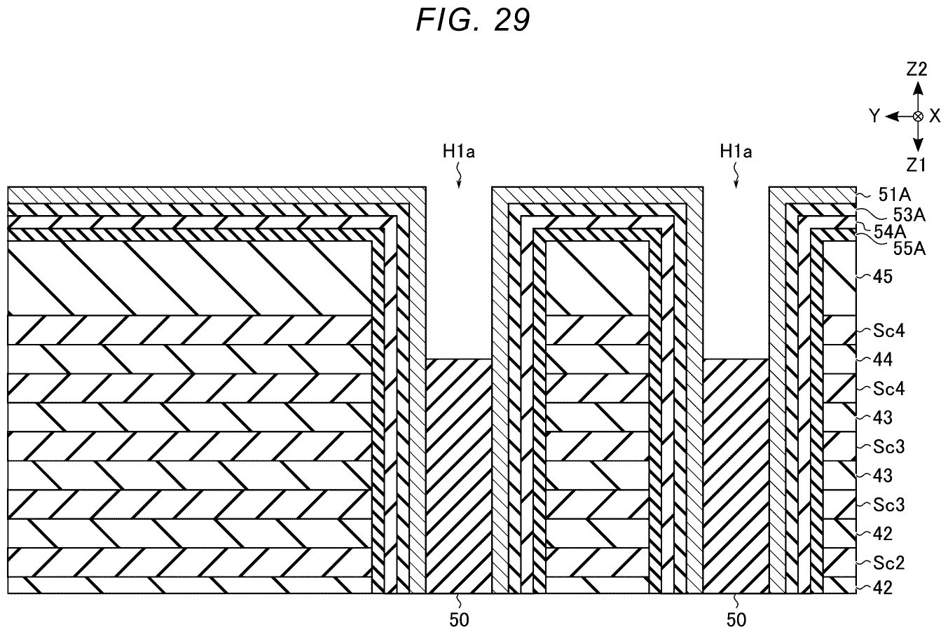

Next, a method for manufacturing the semiconductor memory device 1 according to the second modification will be described with reference to FIGS. 29, 30, and 31. FIGS. 29, 30, and 31 are cross-sectional diagrams for illustrating an example of process steps of the method for manufacturing the semiconductor memory device according to the second modification.

In the step corresponding to the step described with reference to FIG. 13 of the embodiment, the second surface of the core member 50 is located on one side of the second surface of the sacrifice layer Sc4 on the other side, as shown in FIG. 29. As a result, a plurality of holes H1a surrounded by the second surface of the core member 50 and the semiconductor layer 51A are formed on one side of the core member 50.

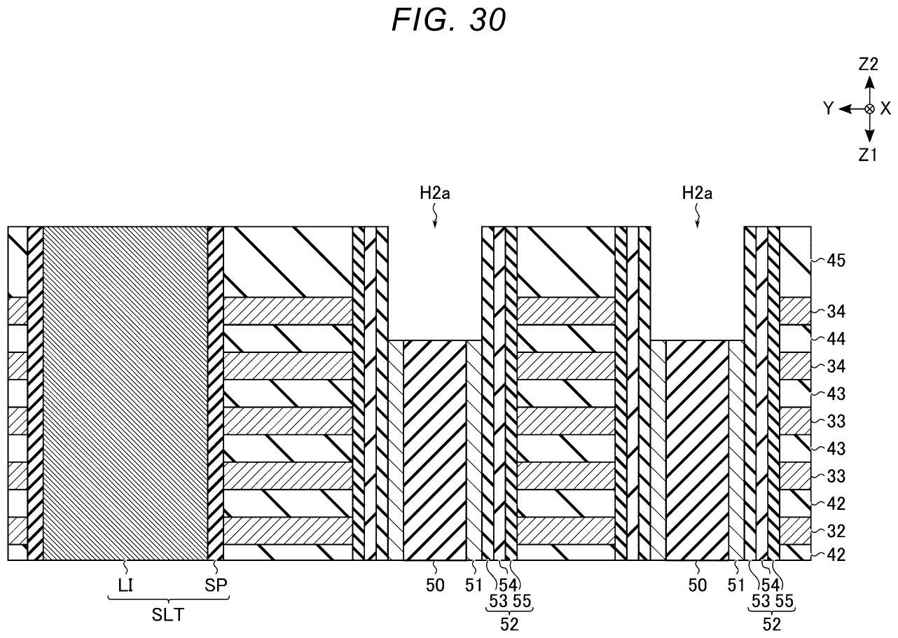

In a step corresponding to the step described with reference to FIG. 17 of the embodiment, for example, a portion on one side of the semiconductor film 51 and all of the semiconductor 56 are removed, as shown in FIG. 30. As a result, a plurality of holes H2a surrounded by the second surface of the core member 50, the second surface of the semiconductor film 51, and the side surface of the tunnel insulating film 53 are formed.

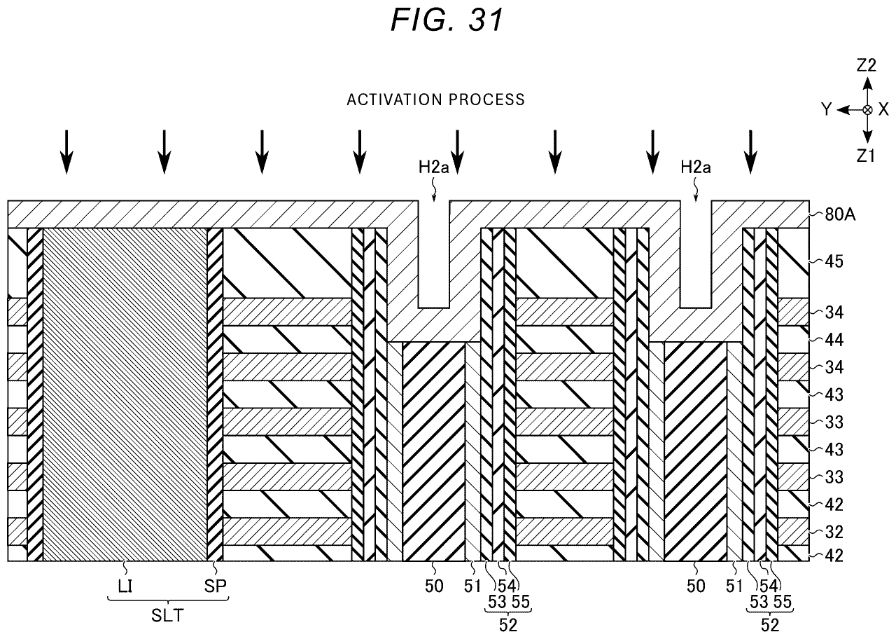

After the semiconductor 80A is formed in the same manner as in the embodiment, an activation process is performed as shown in FIG. 31, similar to the step described with reference to FIG. 18 in the embodiment. As a result, the semiconductor 80A is activated.

Through the steps described above, the semiconductor memory device 1 according to the second modification is manufactured.

The second modification also achieves the same effects or advantages as the embodiment.

### 2.3 Third Modification

In the embodiment, the first modification, and the second modification described above, the case where the cap portion 81 contains a metal material was described, but the embodiment is not limited thereto. The cap portion 81 may contain a semiconductor material. In the following, the configuration of the semiconductor memory device 1 according to the third modification, which is different from the configuration of the semiconductor memory device according to the embodiment, will be described.

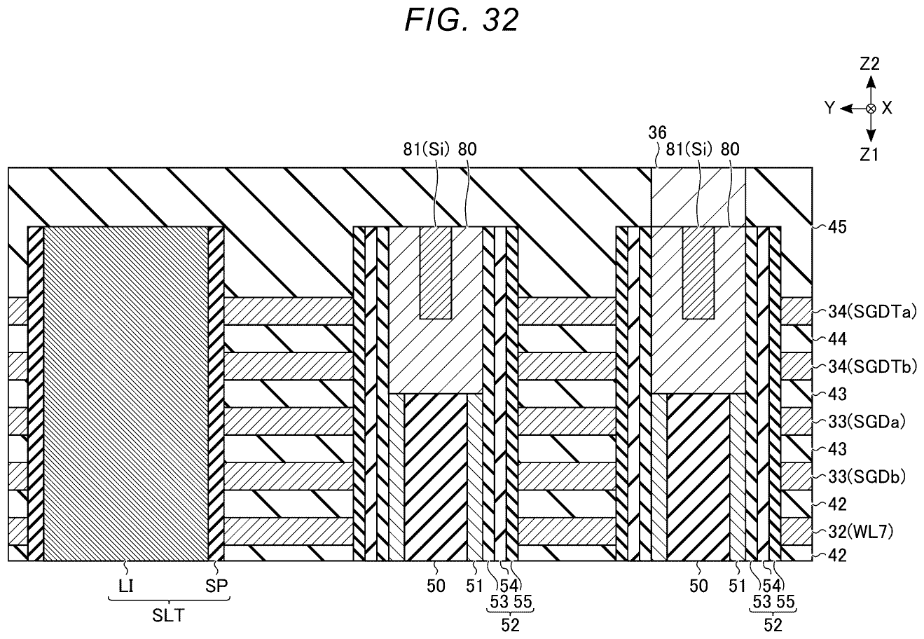

A structure of the memory cell array 10 in the semiconductor memory device 1 according to the third modification will be described with reference to FIG. 32. FIG. 32 is a cross-sectional diagram showing an example of a cross-sectional structure of a memory cell array of the semiconductor memory device according to the third modification. FIG. 32 corresponds to the region shown in FIG. 8 of the embodiment.

In the third modification, the cap portion 81 contains a semiconductor material. The cap portion 81 contains, for example, polysilicon. A crystal structure of the cap portion 81 is different from a crystal structure of the semiconductor portion 80. The semiconductor portion 80 and the cap portion 81 can be distinguished, for example, by a transmission electron microscope (TEM) based on the difference in crystal structures of the portions 80 and 81. The semiconductor portion 80 and the cap portion 81 may be distinguished based on a crystal particle diameter of silicon by, for example, ASTAR™-TEM (TEM using the ASTAR method). A crystal particle diameter of silicon in the cap portion 81 is smaller than a crystal particle diameter of silicon in the semiconductor portion 80, for example.

In the method for manufacturing the semiconductor memory device 1 according to the third modification, in the step described with reference to FIG. 20 of the embodiment, instead of forming a conductor containing a metal material, a semiconductor that is amorphous silicon is formed on the second surface of the semiconductor 80B so as to fill a plurality of holes H2. An annealing process is performed to crystallize the formed semiconductor. As a result, the semiconductor becomes polysilicon. The annealing process is performed at such a low temperature that the generation of fluorine gas from the wiring layer can be prevented. Then, similar to the embodiment, a CMP process is performed to form the semiconductor portion 80 and cap portion 81 corresponding to each memory pillar MP.

Through the steps described above, the semiconductor memory device 1 according to the third modification is manufactured.

The third modification also achieves the same effects or advantages as the embodiment.

### 2.4 Fourth Modification

In the embodiment, first modification, second modification, and third modification described above, the case where the cap portion 81 is provided in a columnar shape having a substantially uniform width along the Z-direction is shown, but the embodiment is not limited thereto. A portion on one side of the cap portion 81 may have a taper shape. In the following, the configuration of the semiconductor memory device 1 according to the fourth modification, which is different from the configuration of the semiconductor memory device according to the embodiment, will be described.

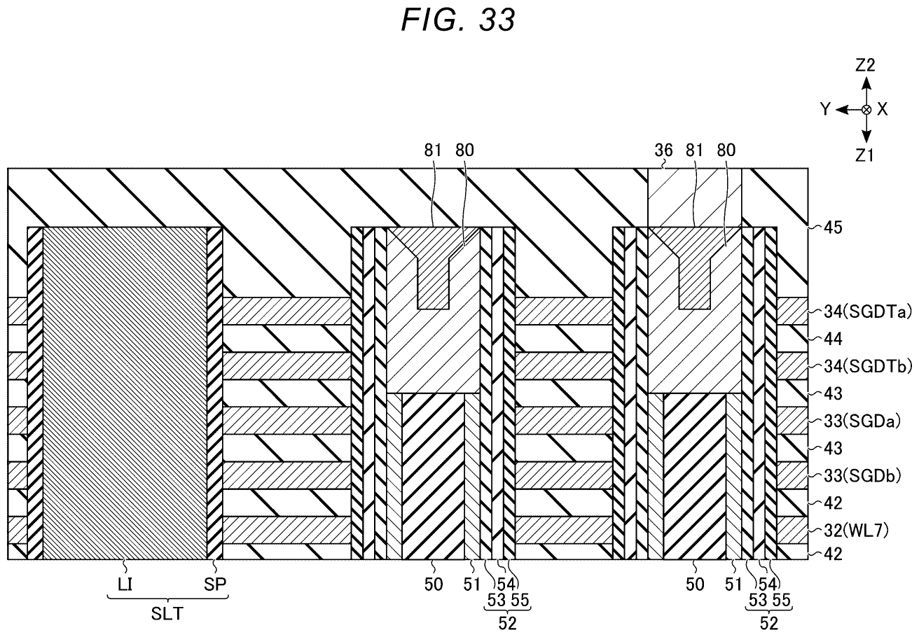

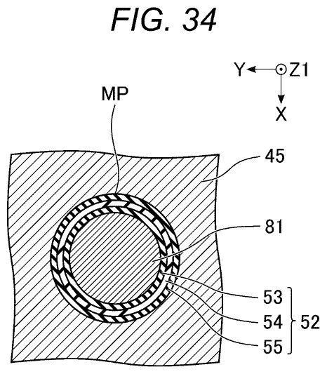

A structure of the memory cell array 10 in the semiconductor memory device 1 according to the fourth modification will be described with reference to FIGS. 33 and 34. FIG. 33 is a cross-sectional diagram showing an example of a cross-sectional structure of a memory cell array of the semiconductor memory device according to the fourth modification. FIG. 33 corresponds to the region shown in FIG. 8 of the embodiment. FIG. 34 is a cross-sectional diagram showing an example of a cross-sectional structure of a memory pillar of the semiconductor memory device according to the fourth modification. FIG. 34 corresponds to a cross-sectional structure of the memory pillar MP at the same height as the second surface of the cap portion 81.

A portion on the other side of the cap portion 81 has, for example, a columnar shape with a substantially uniform width and a portion on one side thereof has a taper shape. The portion having a taper shape of the cap portions 81 has a shape such that a width in the Y-direction increases from the other side toward one side in the Z-direction. Although not shown, that portion also has a shape in which the width in the X-direction increases toward one side in the XZ cross section, and further has a similar shape in any cross section including the Z-direction.

As shown in FIG. 34, the cap portion 81 is provided so as to entirely cover the semiconductor portion 80 when viewed in the Z-direction. As a result, the conductor layer 36 is electrically connected to the semiconductor portion 80 via the second surface of the cap portion 81.

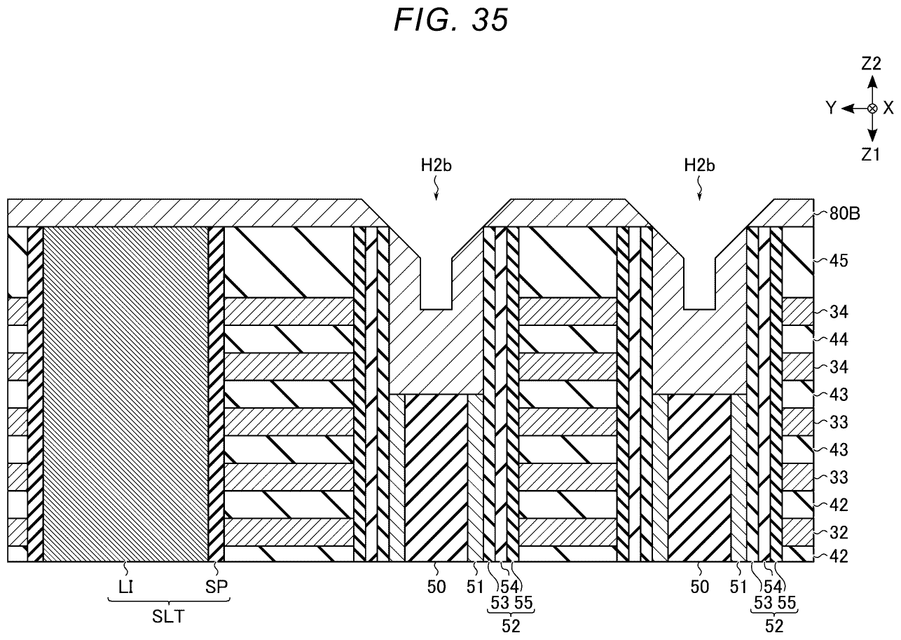

Next, a method for manufacturing the semiconductor memory device 1 according to the fourth modification will be described with reference to FIG. 35. FIG. 35 is a cross-sectional diagram for illustrating an example of a process step of a method for manufacturing the semiconductor memory device according to the fourth modification.

For example, after the semiconductor 80B is formed as shown in FIG. 19 of the embodiment, a portion on one side of the hole H2 is tapered as shown in FIG. 35. As a result, a hole H2b having a shape in which the width in the Y-direction and the X-direction increases toward the Z2-direction is formed on one side.

Then, similar to the embodiment, the semiconductor portion 80 and the cap portion 81 corresponding to each memory pillar MP are formed.

Through the steps described above, the semiconductor memory device 1 according to the fourth modification is manufactured.

The fourth modification also achieves the same effects or advantages as the embodiment.

### 2.5 Fifth Modification

In the embodiment, first modification, second modification, third modification, and fourth modification described above, the case where the second surface of the core member 50 is located on the other side with respect to the conductor layer 34 (select gate line SGDTa) on the most one side was described, but the embodiment is not limited thereto. The second surface of the core member 50 may be located at the same height as the second surface of the conductor layer 34 on the most one side, or on the one side from that height. In the following, the configuration of the semiconductor memory device 1 according to the fifth modification, which is different from the configuration of the semiconductor memory device according to the embodiment, will be described.

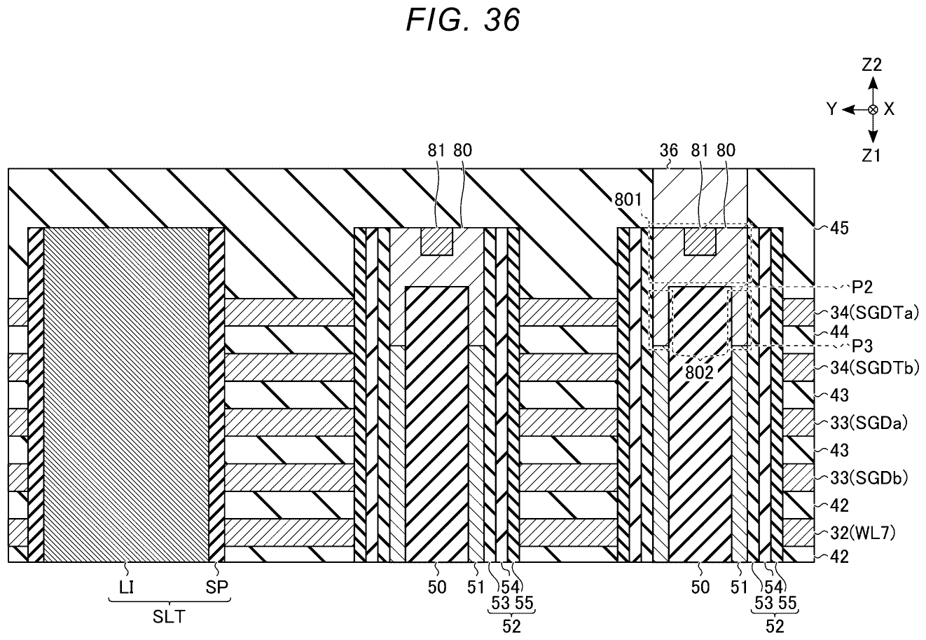

A structure of the memory cell array 10 in the semiconductor memory device 1 according to the fifth modification will be described with reference to FIG. 36. FIG. 36 is a cross-sectional diagram showing an example of a cross-sectional structure of the memory cell array of the semiconductor memory device according to the fifth modification. FIG. 36 corresponds to the region shown in FIG. 8 of the embodiment.

As shown in FIG. 36, the second surface of the core member 50 is located at height P2. The height P2 is, for example, located at the same height as the second surface of the conductor layer 34 (select gate line SGDTa) on the most one side, or located on one side from that height.

The semiconductor film 51 covers the periphery of the portion of the core member 50 included on the other side from the height P3. The height P3 is located, for example, between the conductor layer 34 (select gate line SGDTa) on one side and the conductor layer 34 (select gate line SGDTb) on the other side. The height P3 may be located on the other side with respect to the conductor layer 34 (select gate line SGDTa) on the most one side and on one side with respect to the conductor layer 33 (select gate line SGDa) on the most one side.

The semiconductor portion 80 includes a first semiconductor portion 801 included on one side from the height P2, and a second semiconductor portion 802 included on the other side from the height P2. The first semiconductor portion 801 covers a side surface and a first surface of the cap portion 81. The first semiconductor portion 801 is in contact with the second surface of the core member 50 and the portion of the tunnel insulating film 53 included on one side from the height P2. The second semiconductor portion 802 covers the portion of the side surface of the core member 50 that is on one side from the height P3 and on the other side from the height P2. The first surface of the second semiconductor portion 802 is in contact with the second surface of the semiconductor film 51 at the height P3. The second semiconductor portion 802 is in contact with the first semiconductor portion 801 at the height P2.

With the configuration described as above, in the memory pillar MP, the semiconductor portion 80 is provided in a region, which is surrounded by the second surface of the semiconductor film 51, the portion of the core member 50 on one side of the semiconductor film 51, and the portion of the laminate of films 52 on one side of the semiconductor film 51, excluding the cap portion 81, in a liner shape.

Furthermore, with the configuration of the semiconductor portion 80 as described above, an n-type semiconductor is provided in the region corresponding to the channel of the select transistor STT1. With such a configuration, the semiconductor memory device 1 according to the fifth modification can generate the GIDL current using the select transistor STT1 during an erase operation. Furthermore, if the height P3 is located on one side from a gap between the select gate line SGDa and the select gate line SGDTb, the occurrence of malfunctions caused by fluctuations in the threshold voltage of the select transistor ST1 during selection of the NAND string is prevented.

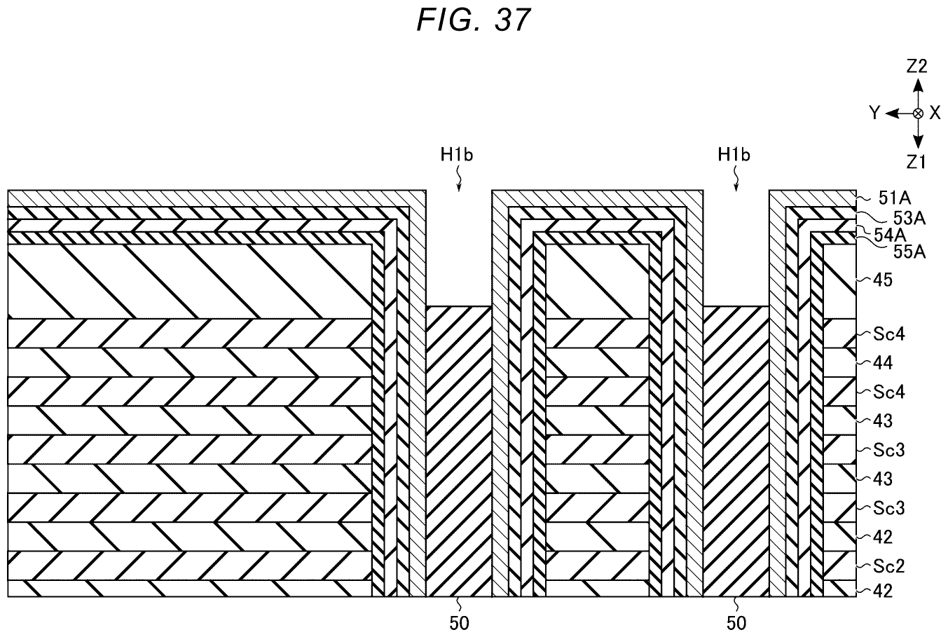

Next, a method for manufacturing the semiconductor memory device 1 according to the fifth modification will be described with reference to FIGS. 37, 38, 39, 40, and 41. FIGS. 37 to 41 are cross-sectional diagrams for illustrating an example of process steps of the method for manufacturing the semiconductor memory device according to the fifth modification. FIGS. 37 to 41 show the region corresponding to FIG. 36.

In the method for manufacturing the semiconductor memory device 1 according to the fifth modification, in a step corresponding to the step described with reference to FIG. 13 of the embodiment, as shown in FIG. 37, the core member 50 is formed, for example, to be embedded to a height equal to that of the second surface of the sacrifice layer Sc4 on the most one side, or to one side from that height. As a result, a plurality of holes H1b surrounded by the second surface of the core member 50 and the semiconductor layer 51A are formed on one side of the core member 50.

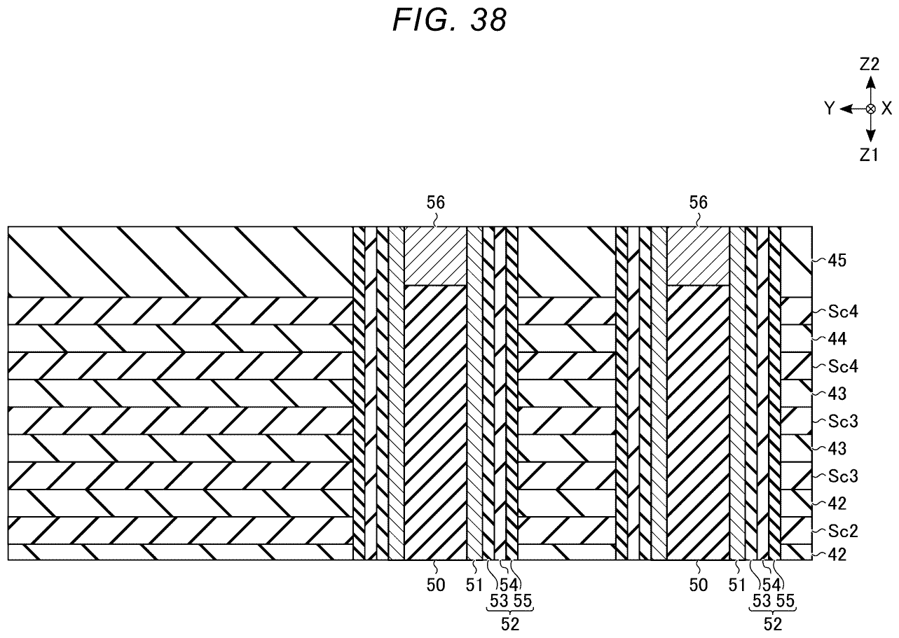

As shown in FIG. 38, by processing similar to the step described with reference to FIG. 14 of the embodiment, the semiconductor film 51, the tunnel insulating film 53, the charge storage film 54, the block insulating film 55, and the semiconductor 56 are formed corresponding to each memory pillar MP.

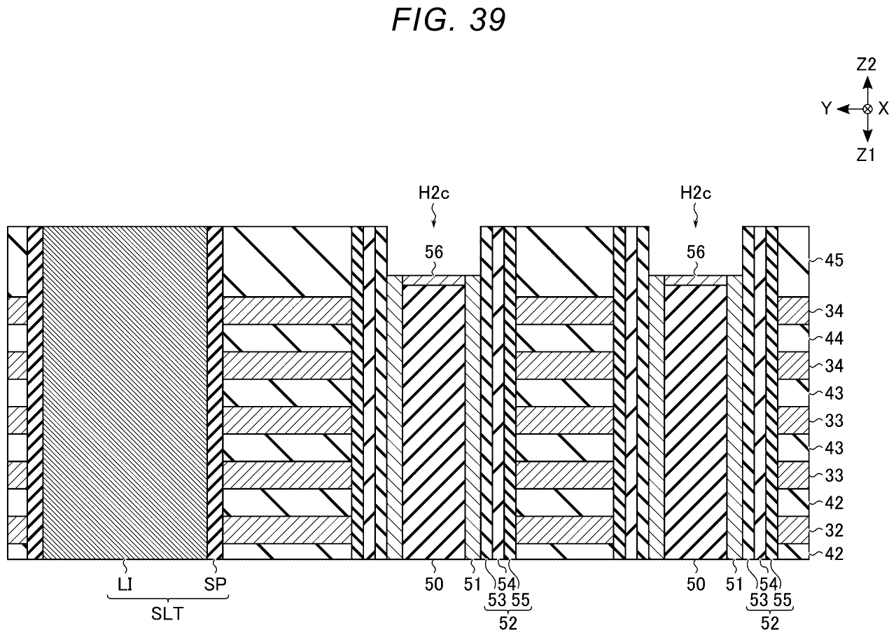

In a step corresponding to the step described with reference to FIG. 17 of the embodiment, as shown in FIG. 39, a portion on one side of the semiconductor film 51 and a portion on one side of the semiconductor 56 are removed. As a result, a plurality of holes H2c surrounded by the second surface of the semiconductor 56, the second surface of the semiconductor film 51, and the side surface of the tunnel insulating film 53 are formed. In this step, the semiconductor 56 may be completely removed.

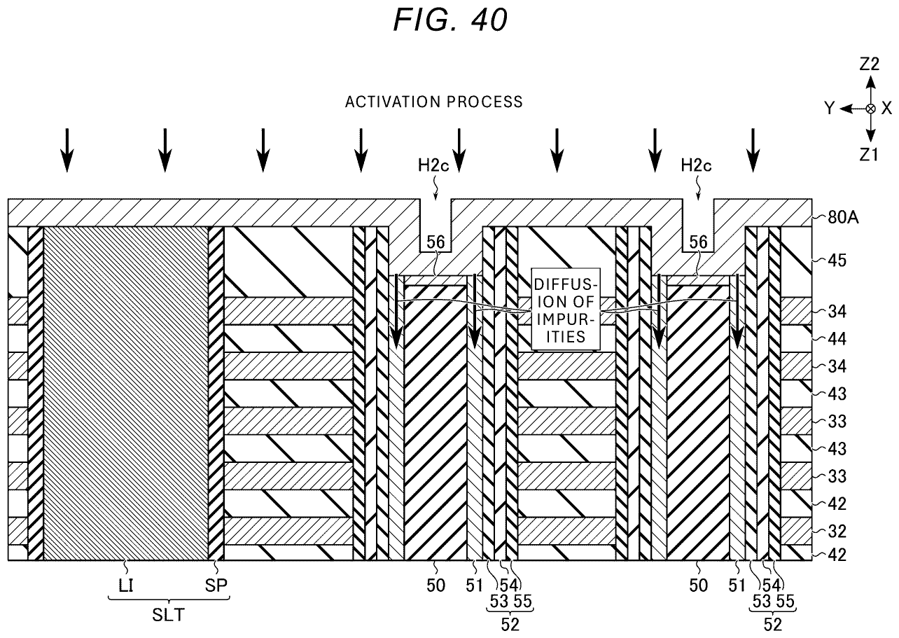

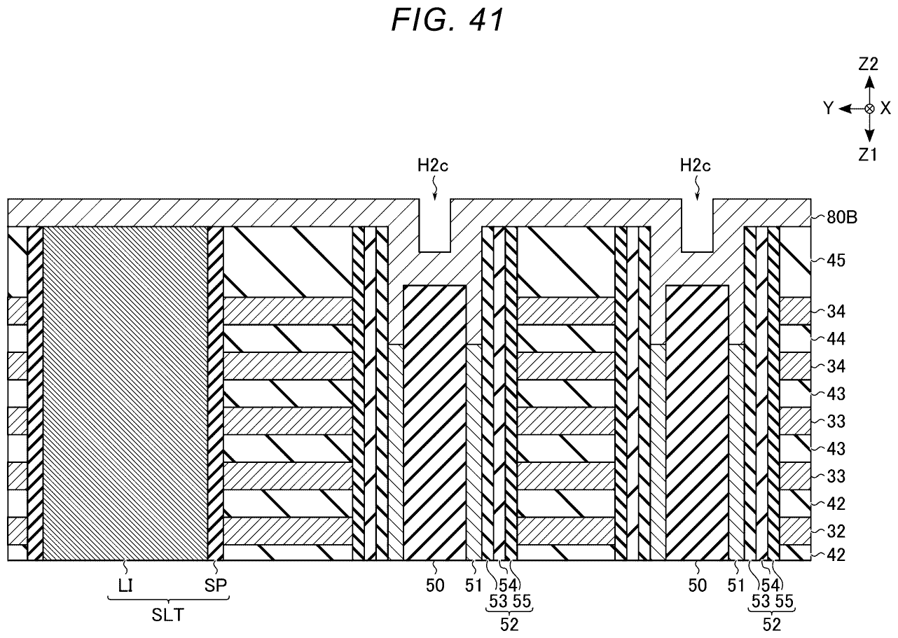

Then, similar to the embodiment, a semiconductor 80A is formed. In addition, in a step corresponding to the step described with reference to FIG. 18 in the embodiment, as shown in FIG. 40, an activation process is performed on the semiconductor 80A to which impurities are added. By the activation process, the semiconductor 80A is activated, and the impurities contained in the semiconductor 80A is introduced into a portion on one side of the semiconductor film 51 by diffusion of the impurities through the portion where the semiconductor 80A and the semiconductor film 51 are in contact with each other. As shown in FIG. 41, the semiconductor 80A is integrated with the portion on one side of the semiconductor film 51 and the semiconductor 56 to form a semiconductor 80B. By the activation process, for example, impurities become substantially uniformly distributed in the semiconductor 80B. The activation process in this step is, for example, an LSA process. When the semiconductor 56 is completely removed in the step described with reference to FIG. 39, in this step, the semiconductor 80B is formed by integrating the semiconductor 80A with the portion on one side of the semiconductor film 51.

Through the steps described above, the semiconductor memory device 1 according to the fifth modification is manufactured.

The fifth modification also achieves the same effects or advantages as the embodiment.

### 3. Others

The embodiment is not limited to forms described above, and various modifications are possible. For example, the structures of the semiconductor portion 80 and the cap portion 81 according to the fourth modification may be applied to the semiconductor memory devices according to the first to third modifications and the fifth modification.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a substrate; and
a memory cell array including:
a source line provided along a surface of the substrate;
a plurality of word lines arranged in a first direction intersecting with the surface of the substrate, each of the word lines extending in a second direction along the surface of the substrate;
a first wiring extending in the second direction, the plurality of word lines being between the source line and the first wiring in the first direction; and
a memory pillar extending from the source line in the first direction, intersecting with the plurality of word lines and the first wiring, wherein
the memory pillar comprises:
a core member extending in the first direction through each of the plurality of word lines;
a semiconductor film provided around a side surface of the core member;
a semiconductor portion extending in the first direction through the first wiring and electrically connected to the semiconductor film, the semiconductor portion being formed of an n-type semiconductor containing an impurity;
a cap portion extending in the first direction in the semiconductor portion, a side surface of the cap portion and a surface of the cap portion facing the core member being covered by the semiconductor portion; and
a laminate of films covering a side surface of the semiconductor film and a side surface of the semiconductor portion.

2. The semiconductor memory device according to claim 1, wherein
the memory cell array further includes a second wiring between the plurality of word lines and the first wiring in the first direction, the second wiring extending in the second direction, and
the core member extends in the first direction through the second wiring.

3. The semiconductor memory device according to claim 2, wherein the first wiring and the second wiring are electrically separated and potentials of the first wiring and the second wiring are independently controllable.

4. The semiconductor memory device according to claim 2, wherein
the memory cell array further includes a third wiring provided between the first wiring and the second wiring in the first direction, the third wiring extending in the second direction, and
the first wiring and the third wiring are electrically connected to each other.

5. The semiconductor memory device according to claim 4, wherein the semiconductor portion extends in the first direction through the third wiring.

6. The semiconductor memory device according to claim 4, wherein the core member and the semiconductor film provided around the side surface of the core member extend in the first direction through the third wiring.

7. The semiconductor memory device according to claim 1, wherein the core member extends in the first direction through the first wiring.

8. The semiconductor memory device according to claim 1, wherein the cap portion contains a metal material.

9. The semiconductor memory device according to claim 1, wherein the cap portion contains a semiconductor material.

10. The semiconductor memory device according to claim 9, wherein
the cap portion contains polysilicon and the semiconductor portion contains polysilicon, and
a crystal structure of the cap portion is different from a crystal structure of the semiconductor portion.

11. The semiconductor memory device according to claim 10, wherein a crystal particle diameter of silicon in the cap portion is smaller than a crystal particle diameter of silicon in the semiconductor portion.

12. The semiconductor memory device according to claim 1, wherein
the cap portion has a first end facing the core member and a second end opposite to the first end, and
a width of the first end of the cap portion in the second direction is smaller than a width of the second end of the cap portion in the second direction.

13. The semiconductor memory device according to claim 12, wherein the cap portion has a taper shape in the second end in which a width of the cap portion decreases as approaching the core member in the first direction.

14. The semiconductor memory device according to claim 1, wherein an impurity concentration of the semiconductor portion is higher than an impurity concentration of the semiconductor film.

15. The semiconductor memory device according to claim 1, wherein the plurality of word lines are provided between the substrate and the source line in the first direction.

16. A semiconductor memory device comprising:
a substrate; and
a memory cell array including:
a source line provided along a surface of the substrate;
a plurality of word lines arranged in a first direction intersecting with the surface of the substrate, each of the word lines extending in a second direction along the surface of the substrate;
a first wiring extending in the second direction, the plurality of word lines being between the source line and the first wiring in the first direction;
a second wiring extending in the second direction between the plurality of word lines and the first wiring in the first direction; and
a memory pillar extending from the source line in the first direction, intersecting with the plurality of word lines, the first wiring, and the second wiring, wherein
the memory pillar includes:
a laminate of films forming an outer periphery of the memory pillar when viewed in the first direction;
a semiconductor film disposed on an inner periphery of the laminate and extending in the first direction through each of the plurality of word lines and the second wiring;
a core member disposed on an inner periphery of the semiconductor film and extending in the first direction through each of the plurality of word lines and the second wiring;
a semiconductor portion extending in the first direction through the first wiring, the semiconductor portion having a liner shape and being in contact with an inner peripheral side surface of the laminate and a surface of the core member facing the semiconductor portion; and
a member that is disposed inside a region of the semiconductor portion having the liner shape and is made of a metal material or a semiconductor material.

17. The semiconductor memory device according to claim 16, wherein the semiconductor film and the semiconductor portion are in contact with each other at a position between the first wiring and the second wiring in the first direction.

18. The semiconductor memory device according to claim 16, wherein the core member extends in the first direction through the first wiring and the semiconductor portion is in contact with the inner peripheral side surface of the laminate on an outer periphery side of the core member.

19. The semiconductor memory device according to claim 16, wherein an impurity concentration of the semiconductor portion is higher than an impurity concentration of the semiconductor film.

20. The semiconductor memory device according to claim 16, wherein the plurality of word lines are provided between the substrate and the source line.
